(19) United States
(12) Patent Application Publication
(10) Pub. No.: US 2015/0340521 A1
(43) Pub. Date: Nov. 26, 2015

(54) Methods and Systems for Controlling Phonon-Scattering

(71) Applicant: THE TRUSTEES OF BOSTON COLLEGE, Chestnut Hill, MA (US)

(72) Inventors: Krzysztof J. Kempa, Chestnut Hill, MA (US); Michael J. Naughton, Chestnut Hill, MA (US)

(21) Appl. No.: 14/652,910

(22) PCT Filed: Dec. 20, 2013
(86) PCT No.: PCT/US2013/077191

§ 371 Date: Jun. 17, 2015

Related U.S. Application Data
(60) Provisional application No. 61/740,061, filed on Dec. 20, 2012.

(51) Int. Cl. H01L 31/0236; H01L 31/0232

(52) U.S. Cl. CPC H01L 31/02366; H01L 31/02327

(57) ABSTRACT

Structures and methods for controlling phonon-scattering are provided. In some embodiments, a metamaterial structure comprises a light absorbing layer (16) capable of absorbing solar energy and converting the absorbed energy into electrical current, a first patterned layer (14) disposed on a light absorbing surface of the light absorbing layer (16), the first patterned layer (14) being configured to increase light absorption in the light absorbing layer (16), and a second patterned layer (60) disposed in proximity to the light absorbing layer (16), the second patterned layer (60) being configured to control phonon-scattering by storing or protecting the hot electron energy in the light absorbing layer (16).

### RELATED APPLICATIONS

This application claims the benefit of and priority to U.S. Provisional Application No. 61/740,061, filed on Dec. 20, 2012, which is incorporated herein by reference in its entirety.

### FIELD

The embodiments disclosed herein relate to structures and methods for controlling phonon scattering by hot electrons in broadband photon absorbers.

### BACKGROUND

Amorphous silicon (a-Si) solar cells have experienced progress over recent years, with stable energy conversion efficiencies exceeding 10% and very low manufacturing costs. However, while the leading solar technology based on crystalline silicon (c-Si) provides efficiencies approaching the theoretical limit of about 30%, a-Si cells are still about a factor of two less efficient than their respective theoretical efficiency limit (about 25%). An identifiable challenge is to improve the efficiency of a-Si and other thin film solar cells in order to fully exploit their advantages in lowering manufacturing costs, and thus dramatically improve the outlook of this environmentally friendly solar energy technology.

Most of today's solar cells suffer from a “color matching” problem. While semiconductor single junction solar cells work efficiently at the light energy (frequency multiplied by Planck's constant) matching the semiconductor energy gap, the solar sunlight spectrum is broadband (comprised of many frequencies in a continuous spectrum). As a result, many sunlight-generated electrons are excited to energies higher than the semiconductor gap, high into the conduction band, and are therefore subject to rapid phonon emission and subsequent conversation of their excess energy into heat (i.e. that above the conduction band minimum for electrons and that below the valence band maximum for holes), instead of electric current. These electrons (and holes) are called “hot electrons” (and “hot holes”), and up to 50% of their energy is lost to heat in a typical single junction solar cell. The efficiency of solar cells would improve if phonon losses of hot electrons, excited above the conduction band edge by high energy photons of the solar spectrum, could be prevented or at least minimized (likewise for holes).

The problem with controlling electron-phonon scattering is that it is a fast process, relative to competing routes to conservation of energy, involving a very rich spectrum of phonon excitations. Attempts have been made to control this process in quantum dots, where the so-called “phonon bottleneck” was demonstrated (U. Bockelman and G. Bastard, Phys. Rev. B 42, 8947 (1990)), and in thermoelectric materials and structures, where a decoupling of the phonon and electron channels is achieved by superlattice structuring, or in nanoparticle composites (M. S. Dresselhaus, G. Chen, M. Y. Tang, R. G. Yang, H. Lee, D. Z. Wang, Z. F. Ren, J.-P. Fleurial, P. Gogna, Adv. Mater. 19, 1043 (2007).). However, these attempts have been only partially successful. Thus, there remains a need for an effective solution for controlling electron-phonon scattering.

### SUMMARY

Structures and methods for controlling phonon-scattering are provided.

According to some aspects illustrated herein, there is provided a metamaterial structure comprising a light absorbing layer capable of absorbing solar energy and converting the absorbed energy into electrical current, a first patterned metallic layer disposed on a light absorbing surface of the light absorbing layer, the first patterned metallic layer being configured to increase light absorption in the light absorbing layer, and a second patterned metallic layer disposed in proximity to the light absorbing layer, the second patterned metallic layer being configured to control phonon-scattering by storing or protecting the hot electron energy in the light absorbing layer.

According to some aspects illustrated herein, there is provided a photovoltaic cell that includes a light absorbing layer capable of absorbing solar energy and converting the absorbed energy into electrical current, a first patterned metallic layer disposed on a light absorbing surface of the light absorbing layer, the first patterned metallic layer being configured to increase light absorption in the light absorbing layer, a second patterned metallic layer disposed in proximity to the light absorbing layer, the second patterned metallic layer being configured to control phonon-scattering in the light absorbing layer, and a rear electrode disposed on a surface of the absorbing layer opposite to the light absorbing surface of the light absorbing layer, the rear electrode and the first patterned metallic layer in electrical communication with the absorbing layer to collect electrical current generated in the light absorbing material.

According to some aspects illustrated herein, there is provided a method for increasing conversion efficiency in a solar cell that includes disposing a first patterned metallic layer on a light absorbing surface of a light absorbing layer, wherein the light absorbing layer is capable of absorbing solar energy and converting the absorbed energy into electrical current; disposing a second patterned metallic layer in proximity to the light absorbing layer; allowing the light absorbing layer to absorb light; and collecting electrical current generated in the absorbing layer by a rear electrode disposed on a surface of the absorbing layer opposite to the light absorbing surface of the light absorbing layer, wherein the first and second patterned metallic layers in combination increase the power conversion efficiency of the absorbed solar energy in to electrical energy.

### BRIEF DESCRIPTION OF THE DRAWINGS

The presently disclosed embodiments will be further explained with reference to the attached drawings, wherein like structures are referred to by like numerals throughout the several views. The drawings shown are not necessarily to scale, with emphasis instead generally being placed upon illustrating the principles of the presently disclosed embodiments.

FIG. 1 illustrates an energy flow diagram In some embodiments structure of the present disclosure.

FIG. 2 illustrates an embodiment of a solar cell including a metamaterial absorber structure of the present disclosure.

FIG. 3 and FIG. 4 illustrate graphs of absorbance as a function of light wavelength for materials with various metamaterial effective dielectric constants and magnetic susceptibilities.

FIG. 5A, FIG. 5B and FIG. 5C illustrate various embodiments of a perforated metallic film layer of the present disclosure.

FIG. 6, FIG. 7, FIG. 8, FIG. 9, FIG. 10, FIG. 11, FIG. 12, FIG. 13, FIG. 14, and FIG. 15 illustrate various embodiments of solar cell structures including a perforated metallic film layer and a plasmonic resonator layer.

FIG. 16A, FIG. 16B and FIG. 16C present an embodiment solar cell structure, its effective medium model, and the vector model of the reflection coefficients in the complex plane, respectively.

FIG. 17A, FIG. 17B, FIG. 17C and FIG. 17D present the total reflectance (R₃=r₃r₃*) vs. normalized frequency (Ω=ω/ω₀=6 μm/λ)

FIG. 18A and FIG. 18B present an embodiment of a structure evolving from honeycomb arrays of quasi-triangular islands, to hexagonal arrays of circular perforations, to a solid film.

FIG. 18C illustrates an in-plane unit cell of an optimized checkerboard super-absorber structure having the following parameters: substrate thickness (Ag: 50 nm), absorber thickness (a-Si: 15 nm), PMF (Ag: 20 nm, a=280 nm, W=145 nm), IF (ITO: 55 nm).

FIG. 18D presents a map of reflectance as a function of size of the structure and wavelength.

FIG. 18E presents a graph of reflectance as a function of wavelength (bold-solid black line) simulated for the structure of FIG. 18C, and various modifications of this structure: without IF (thin-solid line), without NPMF (dashed-dotted line), without IF and NPMF (dotted line). A result for the structure of FIG. 18C, but with a=750 nm and W=390 nm (dashed-bold line).

FIG. 18F presents a graph of the total absorbance of the structure of FIG. 18C, and the partial absorbances in the absorber, silver substrate, and NPMF (marked by arrows).

FIG. 19 illustrates the universal auxiliary function ƒ(x) given by Eq. (8) in Example 3, plotted versus x=Eₖ/E₀.

FIG. 20 illustrates a graph of electron scattering rates of hot electrons in silicon.

While the above-identified drawings set forth the presently disclosed embodiments, other embodiments are also contemplated, as noted in the discussion. This disclosure presents illustrative embodiments by way of representation and not limitation. Numerous other modifications and embodiments can be devised by those skilled in the art which fall within the scope and spirit of the principles of the presently disclosed embodiments.

### DETAILED DESCRIPTION

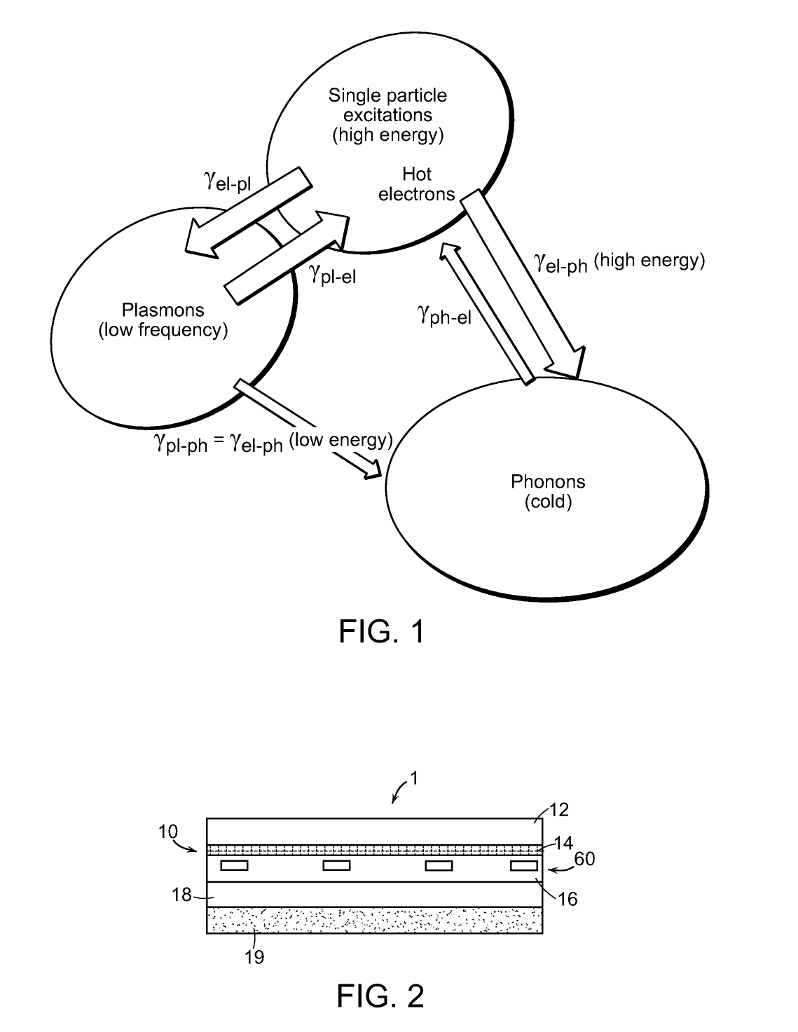

The present disclosure provides systems and methods for controlling electron-phonon scattering. In reference to FIG. 1, the present disclosure provides plasmonic metamaterial nanostructures that can be used to reduce the electron-phonon scattering rate, by providing an alternative, fast electron-plasmon scattering channel. Because the plasmon-phonon and plasmon-photon scattering processes are relatively slow, this provides a mechanism for hot-electron plasmonic protection against phonon emission. The stored/protected energy can be returned to the single particle channel by processes similar to Rabi oscillations, and to plasmon resonance energy transfer (PRET), leading to the formation of a “plasmaron”, a coupled plasmon-electron quasiparticle. This effect could be used to control phonon scattering in various electronic systems, such as solar cells, high temperature superconductors, adjustable transition temperature superconductors, hot electron transistors, thermoelectric coolers, thermoelectric energy recovery devices, superconducting devices such as SQUIDS, and similar devices.

Hot electrons emit phonons at a rapid rate, γₑₗ₋ₚₕ (high energy). Hot electrons can also rapidly emit plasmons in a proximate plasmonic resonator with rate γₑₗ₋ₚₗ, which can be higher (faster) than γₑₗ₋ₚₕ Because the plasmon energy can be designed to be small, the subsequent emission of phonons by the plasmons is at a slower rate: γₚₗ₋ₚₕ (low freq)=γₑₗ₋ₚₕ (low energy), which is much less than γₚₗ₋ₚₕ (high energy). Because plasmons generate hot electrons at a rate γₚₗ₋ₑₗ equal to γₑₗ₋ₚₗ, a plasmonic resonator can act to reduce phonon emission by hot electrons.

In reference to FIG. 2, a metamaterial absorber structure 10 of the present disclosure includes a noncontinuous metal film, such as perforated metallic film (PMF) layer 14, and an absorbing layer 16. Moreover, a plasmonic resonator (PR) layer 60 may also be included. In some embodiments, the metamaterial absorber structure 10 may be used in manufacturing a solar cell 1, where the PMF (or equivalent) layer may serve as a window electrode of the solar cell, that is, the electrode through which the light enters the solar cell, and to provide a light trapping function, and the PR layer may be utilized to enable control over phonon scattering from hot electrons. In some embodiments, the positions of the PR layer and the PMF are reversed. That is, the PR layer is on top and the PMF is embedded in the absorber.

In some embodiments, the absorbing layer 16 is capable of absorbing solar energy and converting the absorbed energy into electrical current. In some embodiments, the absorbing layer is a semiconductor or photovoltaic junction. In some embodiments, the absorbing layer is a p-n junction. In some embodiments, the absorbing layer is a p-i-n junction. In some embodiments, the PMF layer 14 is deposited over the p-doped side of a p-n junction or a p-i-n junction. In some embodiments, the PMF layer 14 is deposited over the n-doped side of a p-n junction or a p-i-n junction. In some embodiments, the absorbing layer 16 is selected from semiconductor materials, including, without limitations, group IV semiconductor materials, such as amorphous silicon, hydrogenated amorphous silicon, crystalline silicon (e.g., microcrystalline polycrystalline, or nanocrystalline silicon), and germanium, group III-V semiconductor materials, such as gallium arsenide and indium phosphide, group II-VI semiconductor materials, such as cadmium selenide and cadmium telluride, and chalcogen semiconductor materials, such as copper indium selenide (CIS) and copper indium gallium selenide (CIGS). In some embodiments, the absorbing layer 16 is made of a material having a refractive index greater than 3. In some embodiments, the absorbing layer 16 is made of a material having a refractive index greater than 4.

By way of a non-limiting example, the absorbing layer 16 is a thin photovoltaic junction of amorphous silicon (a-Si). In some embodiments, the absorbing layer 16 is a thin p-i-n junction of amorphous silicon (a-Si). As used herein, the term “thin photovoltaic junction” refers to photovoltaic junctions or photovoltaic films (which terms may be used interchangeably throughout the instant application) having an overall junction thickness between about 1 nanometer (nm) and about 1000 nm. In some embodiments, a thin photovoltaic junction of the present disclosure has an overall junction thickness between about 10 nm and about 300 nm. In some embodiments, a thin photovoltaic junction of the present disclosure has an overall junction thickness between about 10 nm and about 40 nm. In some embodiments, a thin photovoltaic junction of the present disclosure has an overall junction thickness between about 15 nm and about 30 nm. In some embodiments, a thin photovoltaic junction of the present disclosure has an overall junction thickness of about 40 nm. In some embodiments, a thin photovoltaic junction of the present disclosure has an overall junction thickness of about 15 nm.

In some embodiments, the PMF layer 14 can be a geometrically patterned metallic sheet. In some embodiments, the PMF layer 14 is made of a conductive material to allow the PMF layer 14 to act as a solar cell electrode. In some embodiments, the thickness of the PMF layer 14 is less than 100 nm. In some embodiments, the thickness of the PMF layer 14 is less than 50 nm. In some embodiments, the thickness of the PMF layer 14 is less than 500 nm. Suitable metals include, but are not limited to, silver (Ag), copper (Cu), gold (Au), properly corrosion protected alkali metals, such as aluminum (Al), sodium (Na), potassium (K), etc., among many similar metals. In some embodiments, the thickness of the PMF layer 14 is subwavelength (thinner than the wavelength of optical radiation, or light). In some embodiments, the deposition of the metallic film can be accomplished by nanosphere lithography, nano-imprint lithography or spray coating, as well as other metal deposition methods.

In some embodiments, tuning the geometry of the PMF layer 14 provides the control to tune the light absorption by the metamaterial absorber structure 10 of the present disclosure. When an electromagnetic wave with a certain frequency co enters the metamaterial absorber structure of the present disclosure, the distribution of the total energy can be summarized as T(ω)+R(ω)+A(ω)=1, where T is the transmissivity, R is the reflectivity, and A is the absorptivity. In the context of solar cells, one goal is to maximize the absorption of energy in the absorbing layer 16: A_{PV}(ω)=1−T(ω)−R(ω)−Aₒₜₕₑᵣ(ω), by tailoring the transmission T(ω), the reflection R(ω), and the absorption outside the absorbing layer Aₒₜₕₑᵣ(ω) In some embodiments, T(ω), R(ω) and Aₒₜₕₑᵣ(ω) may be minimized for the majority of the incident energy to be absorbed in the absorbing layer 16. In some embodiments, the minimization of T(ω), R(ω) and Aₒₜₕₑᵣ(ω) can be carried out through the selection of the geometry of the PMF layer, as will be described in more detail in the Examples section. In general, T(ω), R(ω) and Aₒₜₕₑᵣ(ω) are directly linked to, and thus depend on, the optical parameters permittivity, ∈(ω) or the electric response, and permeability, μ(ω) or the magnetic response, of the PMF layer 14. For the metamaterial absorber structure 10 of the present disclosure to be able to operate in a broadband regime, the permittivity and permeability of the PMF layer 14 depend on the frequency (ω) of the electromagnetic wave to be absorbed by the absorbing layer 16 of the present disclosure. This dependence may be achieved by geometric patterning of the PMF layer 14, as described below.

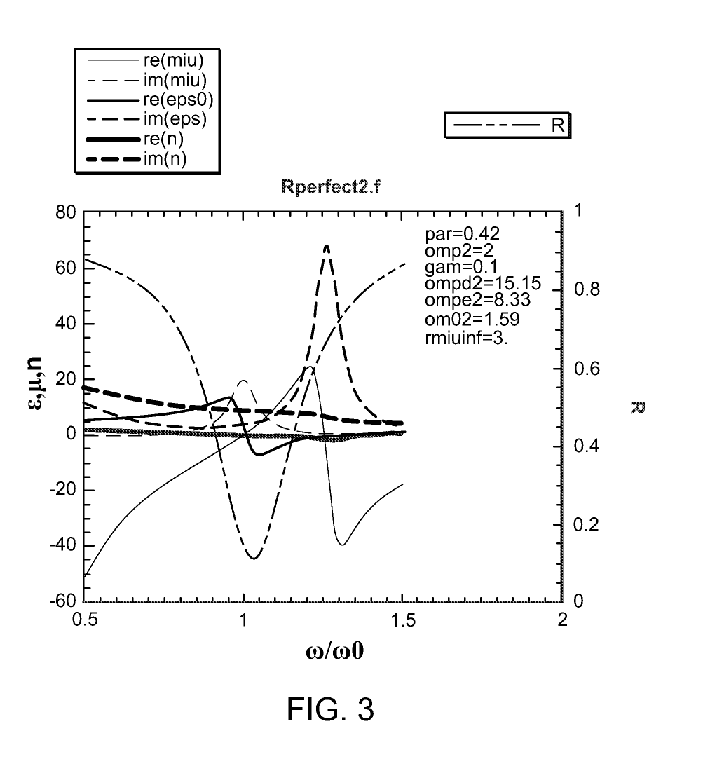

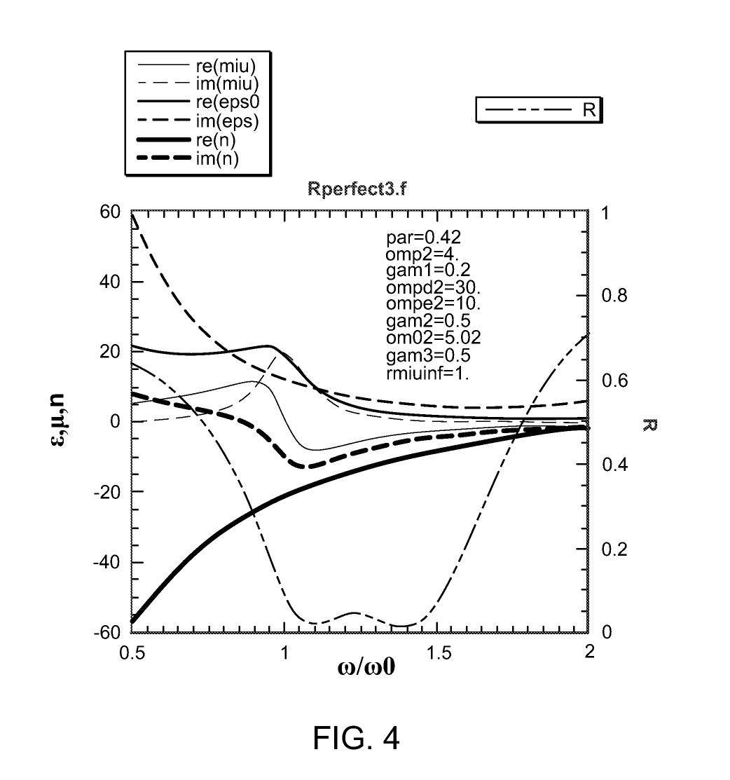

The metamaterial absorber structure 10 has an effective, complex dielectric constant and the magnetic susceptibility. Narrowband, near perfect absorption can be achieved in metamaterial absorber structure 10 by making the metamaterial dielectric constant and the magnetic susceptibility purely imaginary at some frequency, as shown in FIG. 3. In such a scenario, reflectivity R is minimized, thus yielding maximum absorbance (A) of A=1−R. On the other hand, the frequency domain can be chosen in which both the metamaterial dielectric constant and the magnetic susceptibility are complex, but with negative real parts. In some embodiments, this can be achieved by focusing on the frequency range immediately above the magnetic resonance and well below the electric resonance (in the Drude tail). As shown in FIG. 4, a strong broadening of the R minimum is observed, which can further be improved by a better choice of parameters and dependencies.

In some embodiments, the PMF layer 14 is patterned with an array of perforations to yield a desired effective ω⁻¹ dependency of ∈_{eff} and μ_{eff}. ω⁻¹ dependency of ∈_{eff} and μ_{eff} means that these parameters are inversely proportional to the frequency of the radiation (1/ω=ω⁻¹). This is an unusual dependence, and requires a special PMF design. In some embodiments, the array period of perforations ranges between about 100 nm and about 1000 nm. In some embodiments, the array period is subwavelength. In some embodiments, the array period is less than 5000 nm. In some embodiments, the array period is less than 500 nm, less than 400 nm or less than 300 nm. The array may be either periodic or non-periodic. In some embodiments, the perforations 22 can have dimensions between about 70 nm and about 1000 nm. In some embodiments, the perforations 22 can have dimensions that are subwavelength, i.e. hole diameter smaller than the incident light wavelength. In some embodiments, the perforations 22 can have dimensions less than 500 nm, less than 400 nm or less than 300 nm. In some embodiments, the PMF layer 14 comprises an array of metal islands 20. In some embodiments, the metal islands 20 can have dimensions in the sub-wavelength limit. In some embodiments, the metal islands 20 can have dimensions less than 500 nm, less than 400 nm or less than 300 nm. For example, for square metal structures, the sides of the square metal islands can be less than 500 nm, less than 400 nm or less than 300 nm. In some embodiments, the thickness of the PMF layer 14 is subwavelength. In some embodiments, the thickness of the PMF layer 14 is less than 500 nm, less than 400 nm or less than 300 nm. In some embodiments, the thickness of the PMF layer 14 is less than 100 nm. In some embodiments, the thickness of the PMF layer 14 is less than 50 nm or less than 20 nm.

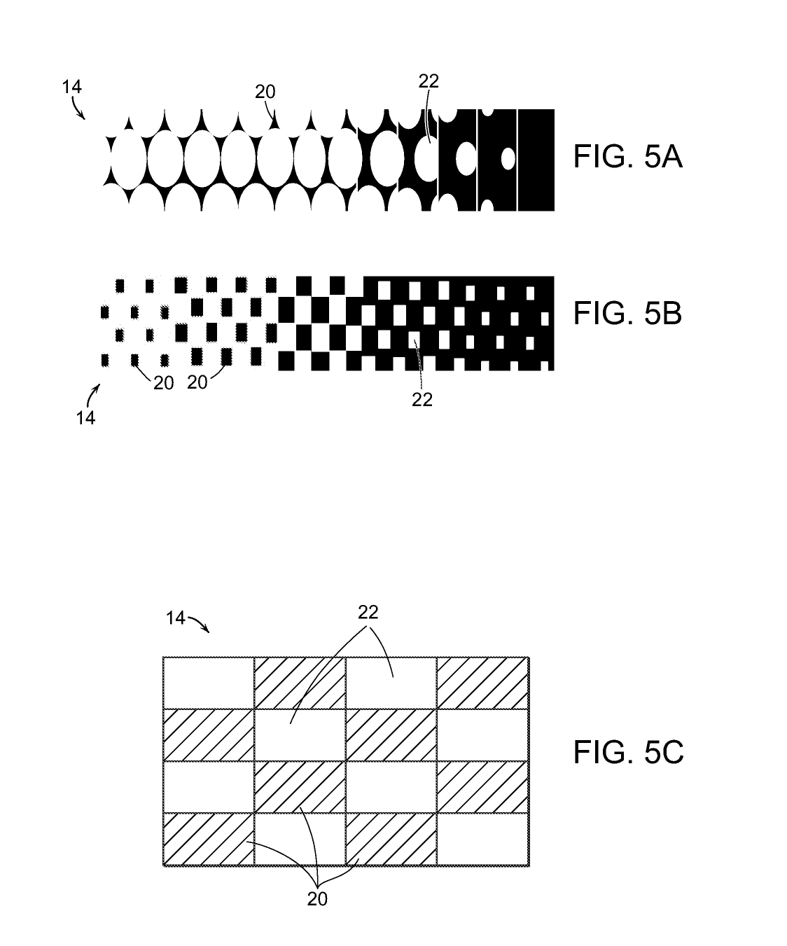

In some embodiments, the shape of the metal islands 20 or perforations 22, their dimensions, and their distribution may be selected so that the structure of the PMF layer 14 is at or near percolation threshold. In some embodiments, the PMF layer 14 may have a percolation threshold structure where periodic structures evolve from an array of islands 20 (on the left hand side) to an array of perforations 20 (on the right hand side), as shown for example in FIG. 5A and FIG. 5B. In some embodiments, the PMF layer 14 may have a checkerboard pattern as shown in FIG. 5C, where metal islands 20 are separated by perforations 22. In some embodiments, the metallic film 14 is a hexagonal array of nearly touching circular perforations 22 (Escheric series). In some embodiments, the PMF layer 14 may have a hexagonal, honeycomb, square, rectangular, triangular or completely random perforations 22 and associated metallic structures 20. Other structures of the PMF layer 14 may be also be used as long as these structures yield a desired effective ω⁻¹ dependency of ∈_{eff} and μ_{eff}. Further embodiments of the PMF layer 14 are described in a commonly-owned U.S. application Ser. No. 14/134,383, filed Dec. 19, 2012, which application is incorporated herein by reference in its entirety.

Referring back to FIG. 2, in some embodiments, to facilitate control of phonon scattering by hot electrons, the metamaterial absorber structure 10 of the present disclosure can further include a metallic plasmonic resonator layer (PR layer) 60. In some embodiments, the PR layer 60 is disposed in proximity to the hot electrons generated in the absorbing layer 16. As used herein, the term “proximity” means that the absorbing layer is within the penetration depth of the electromagnetic near field of the PMF layer 14. This distance may be of the order of the perforation dimension, and so if the perforations are, for example 200 nm in diameter, so is the proximity distance. In some embodiments, to be able to take advantage of hot electrons, the absorbing layer may be between about 10 nm and about 50 nm thick, and so it is always in the proximity for typical perforation dimensions (100-500 nm). A hot electron can be coupled in an open band to the PR layer 60, which sustains plasmon oscillations in a proper frequency range. In this way, the electron can emit a plasmon instead a phonon, as long as the plasmon scattering rate is high enough. In contrast to phonons, plasmons can couple directly back to the single particle channel in the open electronic band, thereby restoring at least part of the stored energy to electrons. The PR layer 60 may be made similarly to the PMF layer, as described above. For example, the PR layer may be manufactured by deposition, lithography or etching. In some embodiments, the PR layer 60 may be formed from a plurality of two-dimensional or 3-dimensional nanoparticles or nanopatterns. In some embodiments, the PR layer 60 may comprise a single layer of nanoparticles or multiple layers of nanoparticles.

As further described in the Examples section, the PR layer 60 may be designed to have desired properties, such as a proper resonant frequency. For example, this can be achieved by controlling the perforation or pattern dimensions and spacing. Other controlling parameters are the choice of the metal, PMF layer thickness, and the interference layer 12. The PR layer 60 may be designed to have a similar structure or a different structure than the PMF layer. In some embodiments, the PR layer 60 may be integral with the PMF layer 14, but the combined layer would have a more complex structure having regions of different geometry, dimension or both.

In some embodiments, a combined structure of the PMF layer 14 and the PR layer 60 may have a plurality of first regions and a plurality of second regions, where the first regions and the second regions may have the same or different spatial size. In some embodiments, the PR layer 60 may be a separate structure from the PMF layer 14.

The spatial size (perforations size, metal structure size, array period, and thickness) of the PMF layer 14 and the PR layer may depend on a desired dominant frequency of absorption by the layer. In some embodiments, the PMF layer 14 and the PR layer 60 are configured to absorb light in a desired frequency range. In general, the size of perforations approximately corresponds to the dominant wavelength absorbed by the structure. For example, a structure having perforations of about 500 nm would be expected to have a dominant frequency of absorption in the sub-micron wavelength range (in the visible spectrum). On the other hand, a structure having perforations of about 1500 nm would be expected to have a dominant frequency of absorption in the sub-micron wavelength range (in the infrared spectrum). Other parameters, such as thickness of the PMF and PR layer, array period, and size of metal structures, may also be varied to design a structure having a dominant frequency of absorption in a desired range. All parameters of the PMF layer and the PR layer, such as structure, sizes, spacing, thickness, material type, control the response of the structures, and the geometry of the structures can be designed to have a desired response, which may be predicted by simulations. In some embodiments, the PMF layer 14 may be designed to absorb in the visible light spectrum, while the PR layer 60 may be designed to absorb or store the energy in the infrared spectrum.

In some embodiments, the PMF layer 14 may have the following dimensions: perforation dimensions of about 50 nm to about 5000 nm, perforation periods of 50 nm to about 5000 nm, metal thickness of about 20 nm to about 100 nm, and random or periodic structure. In some embodiments, the PR layer 60 may have the following dimensions: perforation dimensions of about 20 nm to about 5000 nm; metal structure dimensions of about 2 nm to about 300 nm, with 2D or 3D random or periodic arrangements.

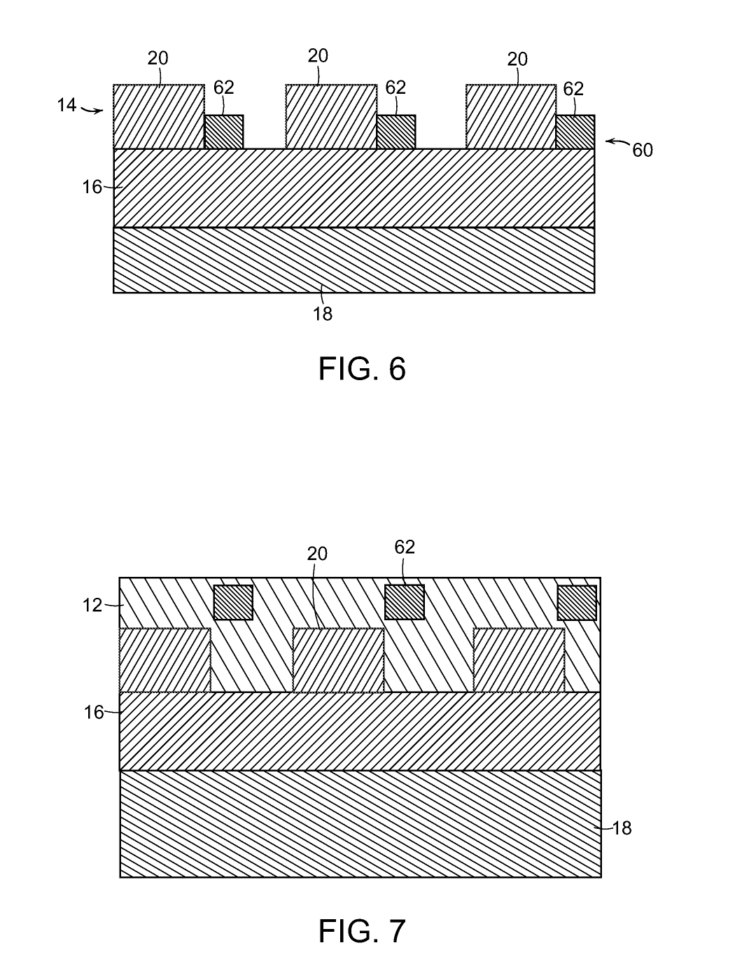

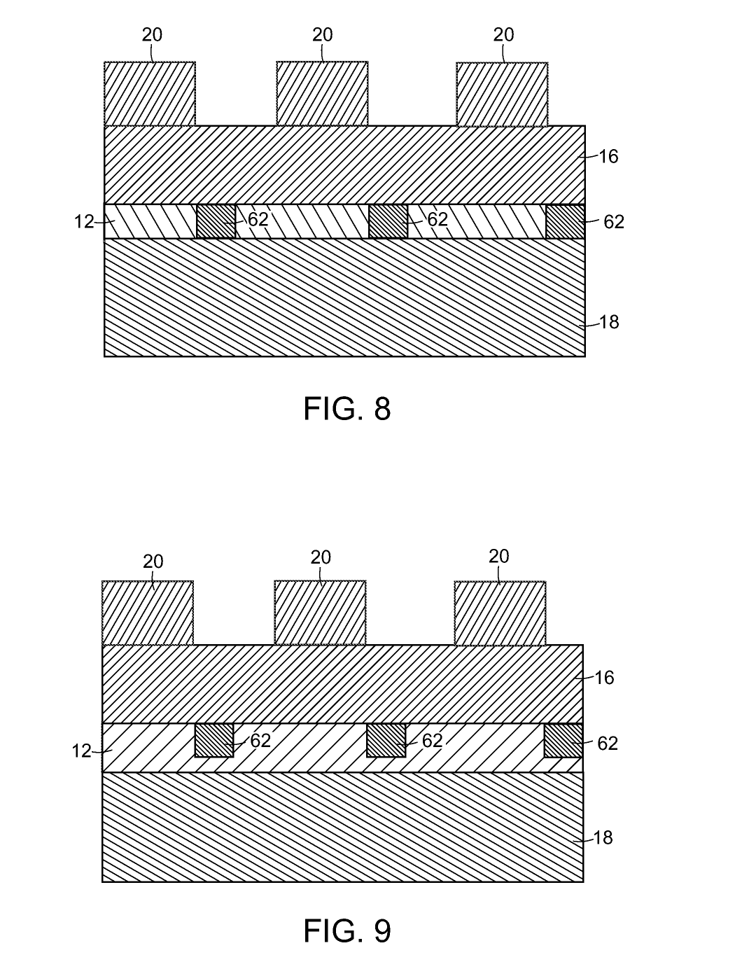

In some embodiments, the PR layer 60 may be formed by perforating a thin metallic film. The deposition of the metallic film can be accomplished by, for example, nanosphere lithography, nano-imprint lithography or spray coating, as well as other known physical or chemical deposition methods. In some embodiments, the PR layer 60 may be formed from the same metallic film as the PMF layer 14, as shown in FIG. 6 below. In some embodiments, the PR layer 60 may be a planar (2D) or 3D array of separated nanoparticles, metallic discs, spheres, discs, hemispheres, squares, or irregular or other nanostructures with appropriate sizes and periods (collectively referred to as nanoparticles). The nanoparticles can be attached to or embedded in the absorbing layer 16 (F. Ye, M. J. Burns, M. J. Naughton, Phys. Stat. Sol. A 209, 1829-1834 (2012)). In some embodiments, this nanoparticle array (periodic or aperiodic) can have plasmonic resonance (bands) designed to occur in the desired frequency range. In some embodiments, the desired range is infrared (IR) radiation. The embedded nature of the nanoparticle arrays may improve the proximity effect. In some embodiments, the design of the nanoparticle array may be configured to assure low radiative losses and low metallic losses. In some embodiments, the nanoparticles embedded in the absorbing layer 16 can be configured to have a minimal effect on the electronic and hole transport in the absorbing layer 16. To that end, the nanoparticles may be coated with an electrically-insulating layer. In some embodiments, the nanoparticle may have the following dimensions: diameter of about 2 nm to about 200 nm, and inter-particle distance (on average if aperiodic) of about 20 nm to about 5000 nm.

As shown in FIG. 6, in some embodiments, the PMF layer 14 and the PR layer 60 may be integrated into a structure that is manufactured, for example, by double texturing a metallic sheet to produce metal structures 20 of the PMF layer 14 of one size and spacing and metal structures 62 of the PR layer 60 of a different size and spacing. In this manner, the combined structure may simultaneously serve two functions: trapping by the PMF metal structures 20 and plasmonic resonance by the PR metal structures 62. While FIG. 6 illustrates metal structures of the PMF layer 14 as larger than the metal structures 62 of the PR layer 60, the size of the structures 20, 62 may be the same or the metal structures of the PMF layer 14 may be smaller than the metal structures 62 of the PR layer 60.

In reference to FIG. 7, the PMF layer 14 and the PR layer 60 may be distinct structures. In some embodiments, the PR layer 60 may be positioned in front, i.e. closer to the light absorbing surface of the solar cell, of the PMF layer 14. As illustrated, there may be an overlap between the PMF layer 14 and the PR layer 60.

In reference to FIG. 8, in some embodiments, the PR layer 60 may be positioned behind the PMF layer 14 and behind the absorbing layer 16. In some embodiments, the PR layer may be positioned at the back surface of the absorbing layer 16 and on the front surface of the rear electrode 18.

In reference to FIG. 9, in some embodiments, the PR layer 60 may be positioned at the back surface of the absorbing layer 16 and away from the front surface of the rear electrode 18, such that there is a gap between the PR layer 60 and the front surface of the rear electrode 18.

In reference to FIG. 10, in some embodiments, the PR layer 60 may be embedded within the absorbing layer 16. The PR layer 60 may be positioned within the light absorbing material at a distance D1 from the light absorbing or front surface of the absorbing layer 16 and a distance D2 from the back surface of the absorbing layer 16. The distances D1 and D2 may range between about 0 and about 50 nm, independently of each other. In some embodiments, the distance D1 between the front surface of the PR layer 60 and the light absorbing surface of the absorbing layer 16 is between about 0 nm and about 30 nm. In some embodiments, the distance D1 between the front surface of the PR layer 60 and the light absorbing surface of the absorbing layer 16 is between about 5 nm and about 30 nm. In some embodiments, the distance D1 is between about 0% and about 80% of the thickness of the light absorbing material. In some embodiments, the distance D1 is between about 1% and about 60% of the thickness of the light absorbing material. In some embodiments, the distance D1 is between about 1% and about 50% of the thickness of the light absorbing material. In some embodiments, the distance D1 is between about 5% and about 60% of the thickness of the light absorbing material. In some embodiments, the distance D1 is between about 5% and about 50% of the thickness of the light absorbing material. In some embodiments, the distance D1 is between about 10% and about 50% of the thickness of the light absorbing material. In some embodiments, the distance D2 between the back surface of the PR layer 60 and the back surface of the absorbing layer 16 is between about 0 nm and about 20 nm. In some embodiments, both D1 and D2 are non-zero. In some embodiments, the distance D2 between the back surface of the PR layer 60 and the back surface of the absorbing layer 16 is between about 5 nm and about 20 nm. Further examples of embedding a metallic nanostructure within a light absorbing layer of a solar cell are described in a pending, commonly-owned International PCT Application No. PCT/US2012/051325, entitled “Embedded Nanopatterns for Optical Absorbance and Photovoltaics,” and filed on Aug. 18, 2012, this application is incorporated herein by reference in its entirety.

In reference to FIGS. 11-15, in some embodiments, the absorbing layer 16 may be positioned between a front resonant tunneling (RT) filter 70 and a back RT filter 72. Each filter may be a dielectric-semiconductor-dielectric heterostructure, similar to the filters used in resonant tunnel diodes (RTD).

In reference to FIG. 11, in some embodiments, the PMF layer 14 and the PR layer 60 may be an integral structure disposed on the front surface of the front RT filter 70. In reference to FIG. 12, the PMF layer 14 and the PR layer 60 may be distinct structures, with the PMF layer 14 disposed on the front surface of the front RT filter 70 and the PR layer disposed in front of the PMF layer 14. In reference to FIG. 13, in some embodiments, the PR layer 60 may be positioned on the front surface of the rear electrode 18 and in contact with the back surface of the back RT filter 72. In reference to FIG. 14, in some embodiments, the PR layer 60 may be positioned at the back surface of the back RT filter 72 and away from the front surface of the rear electrode 18, such that there is a gap between the PR layer 60 and the front surface of the rear electrode 18. In reference to FIG. 15, in some embodiments, the PR layer 60 may be embedded within the absorbing layer 16, sandwiched between two RT filters 70, 72.

Referring back to FIG. 2, in addition to the metamaterial absorber structure 10, the solar cell 1 may further include a interference film 12 disposed on over the PMF layer 14. In some embodiments, the interference film 2 may be air. In some embodiments, the interference layer may be an anti-reflective coating (ARC). The ARC layer 12 may be deposited over the metamaterial absorber structure 10 and is designed to increase transmittance of light into the absorbing layer 16 by reducing the amount of light that is reflected by the absorbing layer 16 and the PMF layer 14. The ARC coating layer 12 may comprise a single coating layer or multiple coating layers. In some embodiments, the ARC layer 12 is a film of dielectric material. In some embodiments, the ARC layer 12 is an oxide, fluoride, nitride, or sulfide of a metal or metalloid, including, but not limited to, silicon (Si), magnesium (Mg), zink (Zn), titanium (Ti), tin (Sn), cerium (Ce) and similar materials. Suitable specific examples of suitable anti-reflective coatings include, but not limited to, MgF₂, ZnS, MgF₂, TiO₂, SiO₂, SiNₓ, CeO₂ and similar materials. Other known and commonly used antireflective coatings may also be used with embodiments disclosed herein. In some embodiments, the thickness of the ARC layer 12 is subwavelength. In some embodiments, the thickness of the ARC layer 12 is less than 100 nm. In some embodiments, the thickness of the ARC layer 12 is less than 50 nm. In some embodiments, the thickness of the ARC layer 12 is less than 500 nm. Detailed design considerations and governing principles for an ARC method suitable for use with the metamaterial absorber structure 10 of the present disclosure are discussed in a pending co-owned International PCT Application No. PCT/US2012/044346, entitled “Super-Transparent Electrodes for Photovoltaic Applications,” and filed on Jun. 27, 2012, this application is incorporated herein by reference in its entirety.

Referring back to FIG. 2, the solar cell 1 may further include a rear electrode 18 disposed on the back side of the absorbing layer 16, that is, the side opposite the light absorbing surface of the absorbing layer 16. The rear electrode 18 may be made of a metal, such as, by example, aluminum, gold or another conductive metal. The rear electrode 18, in combination with the PMF layer 14, collects electrical current generated in the absorbing layer 16. The photovoltaic cell 1 may also include a substrate 19, which may provide additional structural support for the photovoltaic cell 1. In some embodiments, the substrate 19 may be made of glass or metal.

### EXAMPLES

Examples (actual and simulated) of using the devices and methods of the present disclosure are provided below. These examples are merely representative and should not be used to limit the scope of the present disclosure. A large variety of alternative designs exist for the methods and devices disclosed herein and are within the spirit and the scope of the present disclosure. The selected examples are therefore used mostly to demonstrate the principles of the methods and devices disclosed herein.

### Example 1

### Theoretical Predictions of Suitable PMF Structures

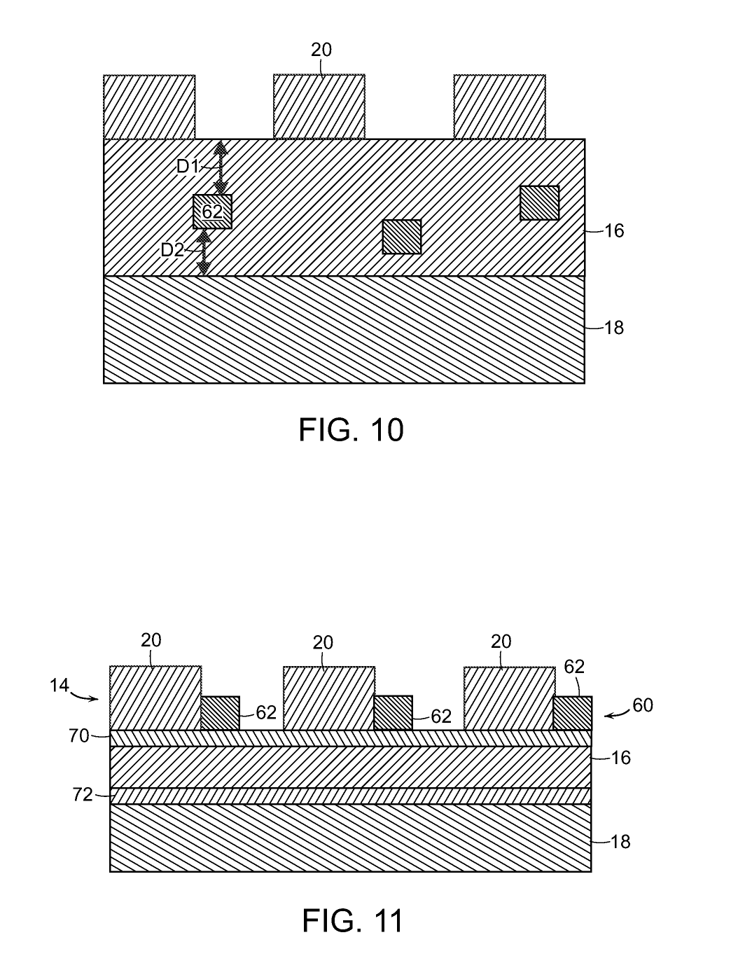

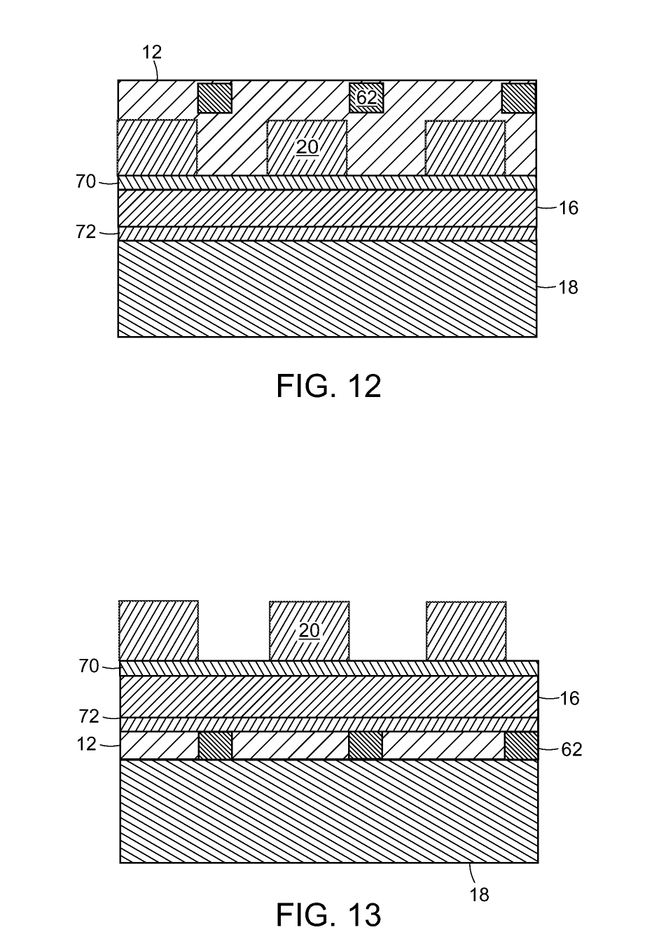

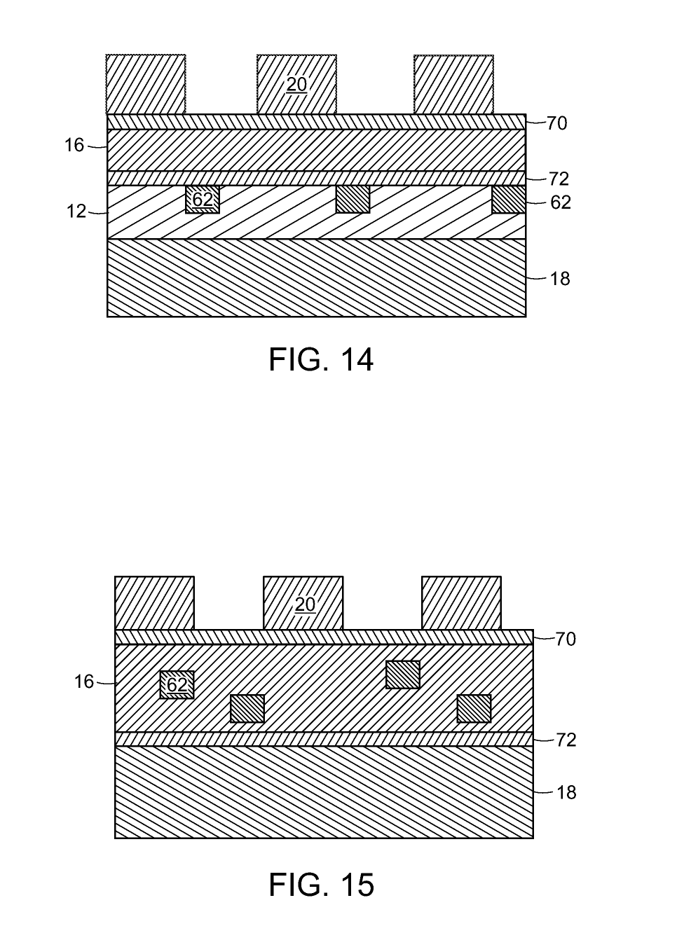

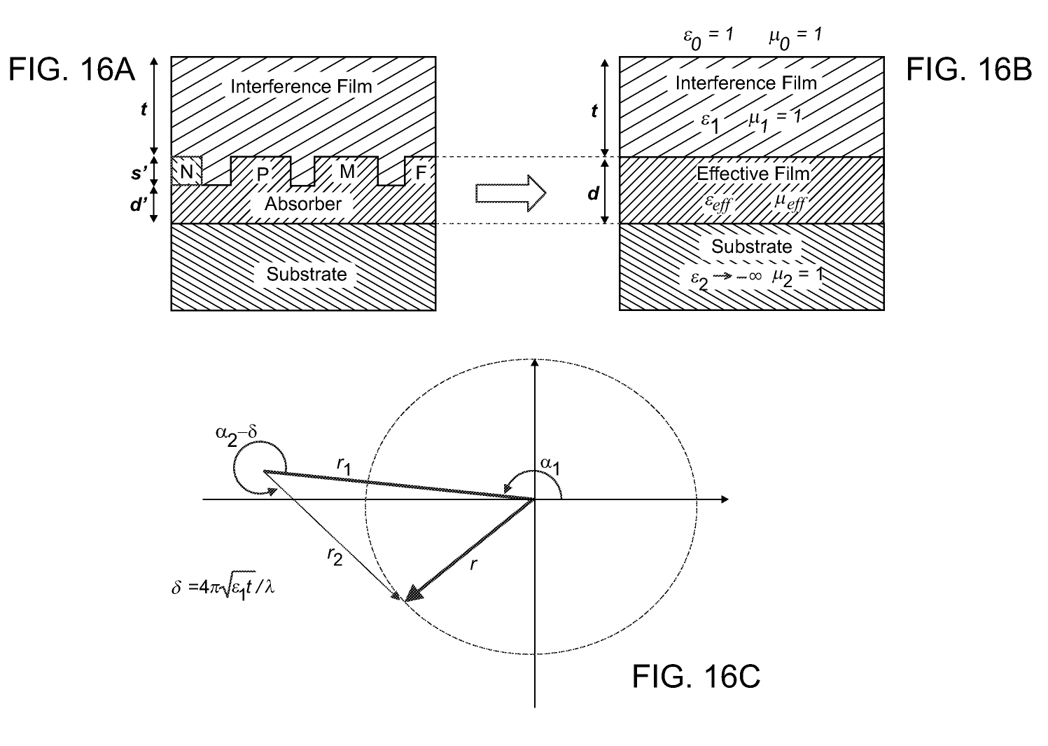

A cross-section of a fragment of the proposed structure is shown schematically in FIG. 16A. It has a basic form of a typical photovoltaic device in a simple planar configuration: a Ag substrate (bottom electrode), an absorber film (the p-i-n junction) of thickness d′, an electrically continuous and nanoscopically perforated metallic film (NPMF) of thickness s′, which acts as a transparent “window” electrode of the cell, and finally an interference film (IF) of thickness t. Reflection suppression is likely in this structure, based on the simplified analysis described below. These conclusions can be confirmed, and the efficiency of a solar cell estimated based on this analysis by employing quantitative first principles simulations.

A cross-section of a fragment of the proposed structure is shown schematically in FIG. 16A. It has a basic form of a typical photovoltaic device in a simple planar configuration: a Ag substrate (bottom electrode), an absorber film (the p-i-n junction) of thickness d′, an electrically continuous and nanoscopically perforated metallic film (NPMF) of thickness s′, which acts as a transparent “window” electrode of the cell, and finally an interference film (IF) of thickness t. Reflection suppression is likely in this structure, based on the simplified analysis described below. These conclusions can be confirmed, and the efficiency of a solar cell estimated based on this analysis by employing quantitative first principles simulations.

For d and the NPMF perforation dimensions<<λ (subwavelength limit), one can employ the effective medium model, and represent the structure as a simple planar layer stack shown in FIG. 16B, for which an analytic solution is available. In this stack, the absorber-NPMF pair is represented by a metamaterial effective film (MEF), with ∈_{eff}, μ_{eff}.

By employing the Fresnel method, the total reflection coefficient from the proposed model structure with IF (at normal incidence, at the air-IF interface) is given by

r=ƒ(r₁,r₂,\sqrt{∈₁}t/λ) (1)

r₂=ƒ(r₁,r₃,0)=|r₂| exp(iα₂) (2)

r₃=ƒ(r_{eff},−1,n_{eff}d/λ) (3)

where the auxiliary function

$$f ( x , y , z ) = \frac{x + y exp ( - i 4 π z )}{1 + xy exp ( - i 4 π z )} {\approx }_{xy << 1} x + y exp ( - i 4 π z ) \qquad ( 4 )$$

In these formulas, r₁ is the Fresnel reflection coefficient for the air-IF interface, given by r₁=(1−\sqrt{∈₁})/(1+\sqrt{∈₁})=|r₁| exp(iα₁), r₂ is the reflection coefficient for the structure at the IF-MEF interface, r₃ is the total reflection coefficient from the structure without IF, and r_{eff}=(1−η)/(1+η) is the Fresnel coefficient at the air-MEF interface. The refractive index of the MEF is η_{eff}=\sqrt{∈_{eff}μ_{eff}} (Im[n_{eff}]>0), and the wave impedance is given by η_{eff}=\sqrt{∈_{eff}/μ_{eff}} (Re[η_{eff}]>0) [Smith, D. R.; Schultz, S.; Markog, P.; Soukoulis, C. M. Phys. Rev. B 2002, 65, 195104.]. In addition to the dielectric function ∈_{eff}, MEF can have a magnetic permeability μ_{eff}≠1, which is a result of the coupling between NPMF and the metallic substrate. A free standing, strictly two dimensional NPMF would have necessarily μ_{eff}=1, since the in-plane magnetic field of the incoming wave cannot induce any currents in the film: the Lorentz force in this case has only a perpendicular (to the film) component. However, in the presence of the metallic substrate, currents can be induced between NPMF and the substrate (via capacitive coupling), which subsequently form closed loops that can lead to nonzero magnetic susceptibility. Since x and y are in general complex, the approximated part of Eq. (4) represents a vector sum of x and y in a complex plane, and then vanishing r according to Eq. (1) requires that the sum of vectors r₁ and r₂ vanishes (see FIG. 16C). Expanding around the wavelength λ₀ at which this vanishing occurs, assuming that r₁ and r₂ are wavelength independent, the reflectance is

R=rr*∝(1−λ₀/λ)² (5)

Numerical evaluation of this equation shows that, surprisingly, the reflectance suppression is broadband, with R<10% in the entire visible range (provided that λ₀ is chosen in the middle of this range). In addition, FIG. 16C shows as follows:

|r₁|+|r|≧|r₂|≧|r₁|−|r| (6)

This inequality shows that the overall suppression is also tolerant of the specific values of |r₂|. For example, suppressing R below 10%, while employing a typical dielectric with n₁=\sqrt{∈₁}≈2 (i.e., |r₁|≈0.3), requires only that |r₂|<0.6. If r₂ is frequency (ω) independent (or slowly varying), this essential vector cancellation can be always assured by adjusting t, which linearly controls the angle between the two vectors. Thus, a slow r₂ variation with frequency is important for achieving the broadband reflectance suppression in the structure.

According to Eq. (2), r₂ independency on ω follows from independency of r₃ on ω*r₃ is given by Eq. (3), and represents the reflection coefficient of the model structure without the interference film. r₃ is independent on ω only if

∈_{eff} and μ_{eff}∝ω⁻¹ (7)

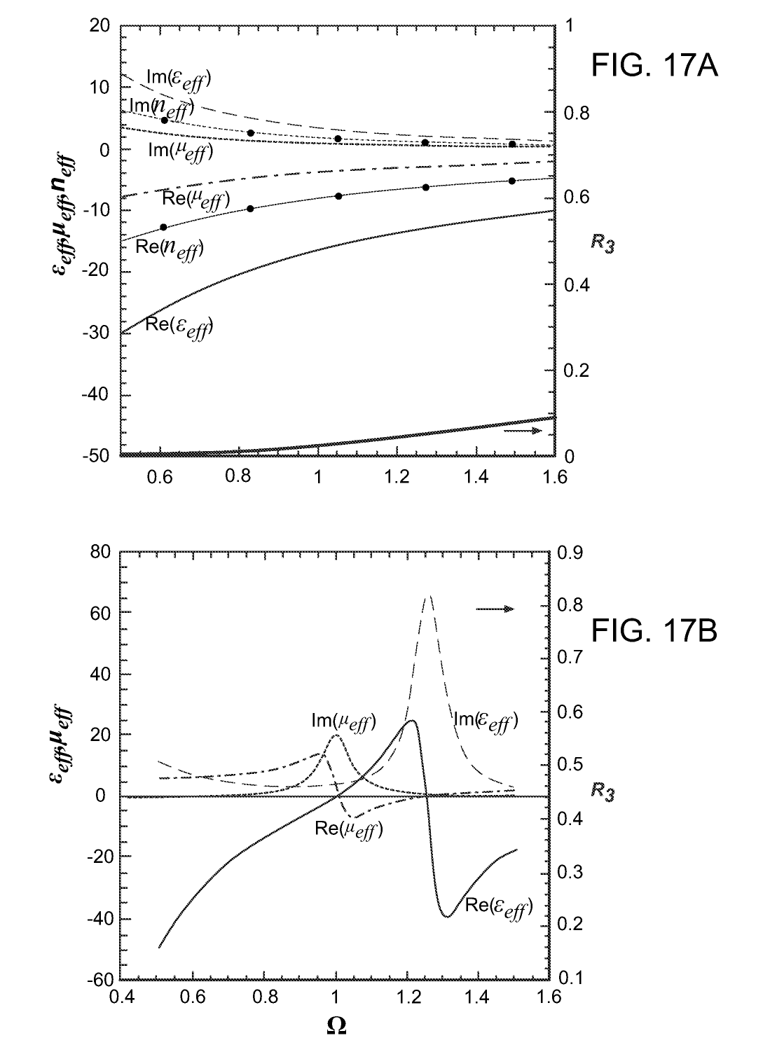

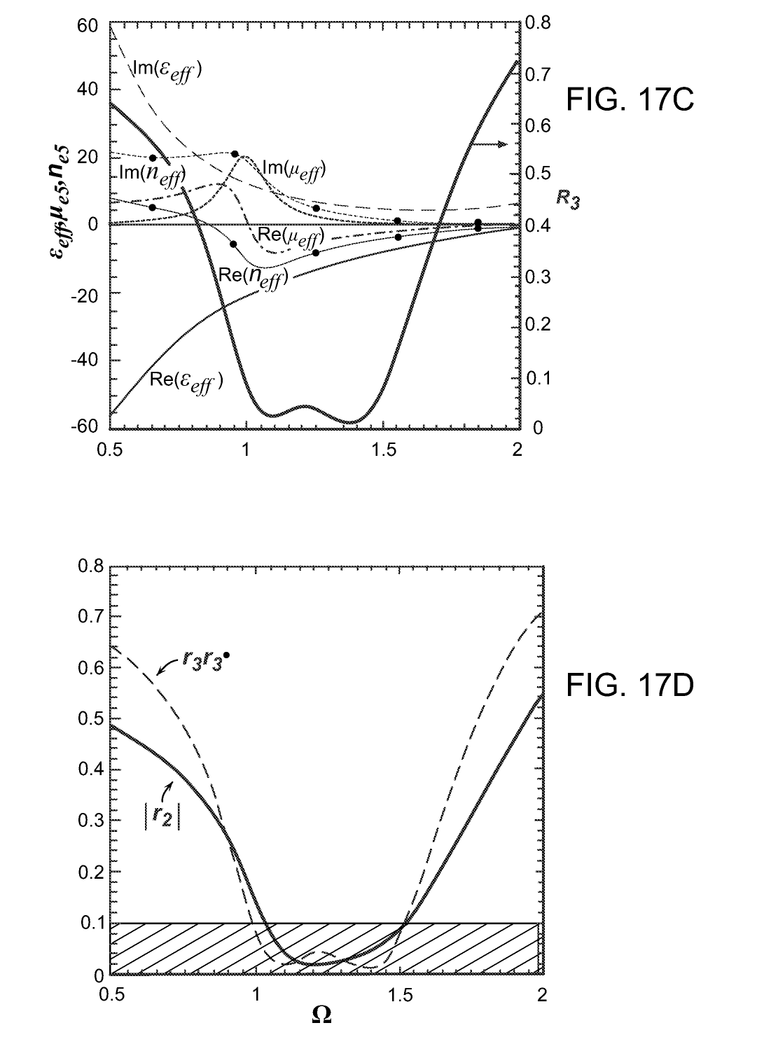

FIG. 17A, FIG. 17B, FIG. 17C and FIG. 17D present the total reflectance R₃=r₃r₃* vs. normalized frequency Ω=ω/ω₀=6 μm/λ, calculated from Eq. (3) (black bold line), and the corresponding extracted ∈_{eff}, μ_{eff} and n_{eff} for: structure with a modeled response ω⁻¹ (FIG. 17A); structure with resonant (plasmonic) resonances (FIG. 17B); and modified structure with separated plasmonic resonances (FIG. 17C). In FIG. 17D, R₃=r₃r₃* taken from FIG. 17C (dashed line), and the corresponding |r₂| (solid line) obtained from Eq. (2) for the modified structure with separated plasmonic resonances. The shaded region in FIG. 17D is the corresponding range of R<0.1, for this structure with an added interference film; this range is very broad, and exceeds the entire frequency range in this plot.

FIG. 17A shows R₃=r₃r₃*, calculated from Eq. (3) vs. normalized frequency, for the structure of FIG. 16B (but without IF), with ∈_{eff} and μ_{eff} modeled to have the approximate ω⁻¹ dependency:

$$A - \frac{B}{ω + i γ} ,$$

where A, B, and γ are constant. Plotted are also the corresponding ∈_{eff}, μ_{eff}, and n_{eff}. The resulting R₃ is small (<10%) in a very broad frequency range, as expected. The broadband suppression of R follows. Note, that for vanishing r₃, r₂≈−r₁ and finally r≈r₁−r₁ exp(−i4π\sqrt{∈₁}t/λ), which vanishes if λ₀=2\sqrt{∈₁}t. This action of IF resembles that of the usual anti-reflection coating (ARC) [Heavens, O. S. Optical properties of thin solid films. Dover Publications, Inc.; New York, 1965.]., except for different λ₀. Eq. (5) thus holds, assuring a broadband suppression of R as well, even if r₃ is not very small.

The ω⁻¹ dependency of ∈_{eff} and μ_{eff} is unusual for an effective medium (in fact this for cannot be correct in the entire frequency range, since it violates the f-sum rule). FIG. 17B shows R₃ for a structure with the usual dependency of ∈_{eff} and μ_{eff} (Kempa, K. Phys. Rev. B 2006, 74, 033411.): sum of Lorentzian terms, each representing a localized plasmonic resonance (e.g., electric Mie resonance)

$$A + \sum \frac{B}{C - ω ( ω + i γ )} ,$$

where A, B, C, and γ are constant. In contrast to FIG. 17A, the reflectance suppression occurs now in a very narrow band. The model parameters have been adjusted to represent the structure in which such narrow band super-absorption (R very close to 0) was recently demonstrated, both by simulations and experiments (Hao, J.; Wang, J.; Liu, X.; Padilla, W. J.; Zhou, L.; Qiu, M. Appl. Phys. Let. 2010, 96, 251104.). In this structure the reflectance suppression relies on a strong interaction between the magnetic and electric resonances in the effective film; note that in this case (see FIG. 17B) the two resonances are very close together, and the minimum of R₃ occurs at the normalized frequency Ω≈1, which is simultaneously the de-localized electric bulk plasmon frequency (Re[∈_{eff}]=0), and the localized magnetic plasmon frequency (Im[μ_{eff}]=maximum). The resonant character of the reflectance suppression comes directly from the resonant character of this plasmonic interaction.

The ω⁻¹ dependency, required for the broadband operation, can approximately occur only in properly engineered structures, and in a limited frequency band away from these plasmonic resonances. To test this idea, the model parameters were changed leading to FIG. 17B, by substantially increasing the C parameter in ∈_{eff}, i.e., by blue-shifting the electric plasmonic resonance, away from the magnetic resonance (still at Ω≈1). The de-localized electric bulk plasmon occurs at Ω≈2.2. Thus, a window opens up in-between these resonances, in which both ∈_{eff} and μ_{eff} monotonically decay, resembling the ω⁻¹ dependency, as shown in FIG. 17C. The resulting R₃, also shown in this figure, is suppressed in a much broader band as expected, and in a non-resonant region. Re(n_{eff}) is negative in the window, indicating that the structure is a negatively refracting (left-handed) metamaterial in this frequency range. The same happens for the case shown in FIG. 17A. This is related to the fact, that the coexistence of propagating bulk and surface plasmon modes in the effective film is required to facilitate an efficient reflectance suppression.

The presence of the IF film helps to broaden this response further. The corresponding |r₂| from Eq. (2) was calculated. FIG. 17D shows both, R₃=r₃r₃*, and |r₂|. While R₃ is suppressed to below 10% only in a relatively narrow band (1<Ω<1.5), |r₂| is less than 0.6 in the entire frequency range shown, and beyond. Thus, as discussed below the inequality (6), this assures less than 10% overall reflectance R in this very broad frequency range (see the shaded region in FIG. 17D), i.e., much broader super-absorption band than that of the structure alone, without the interference film.

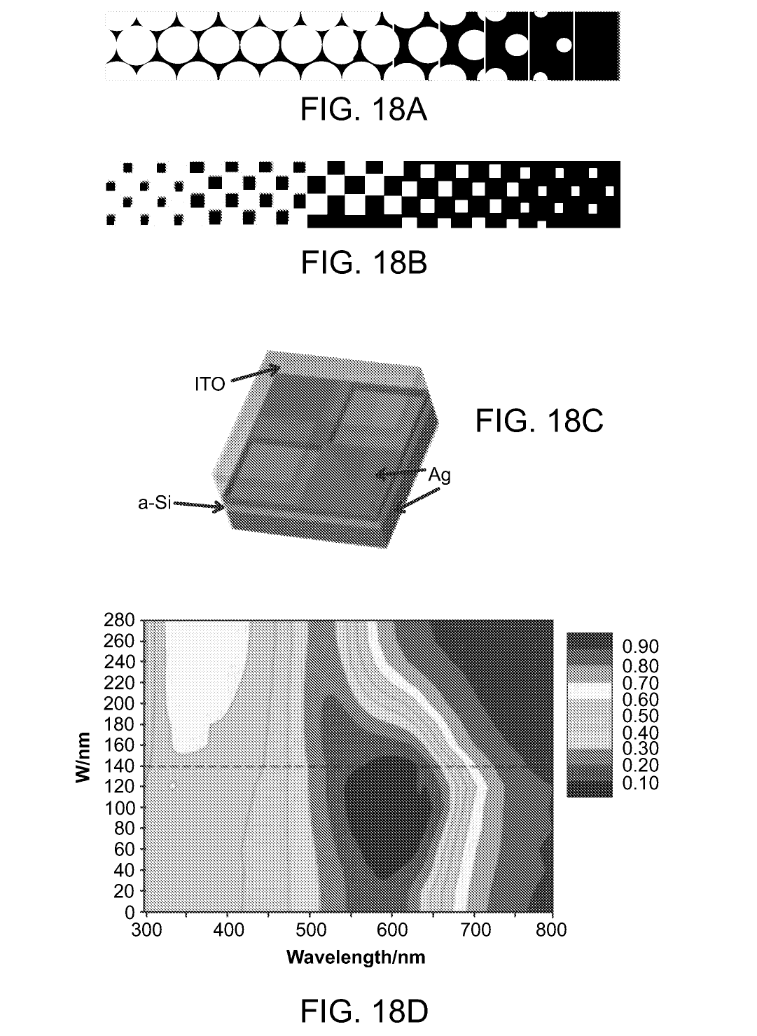

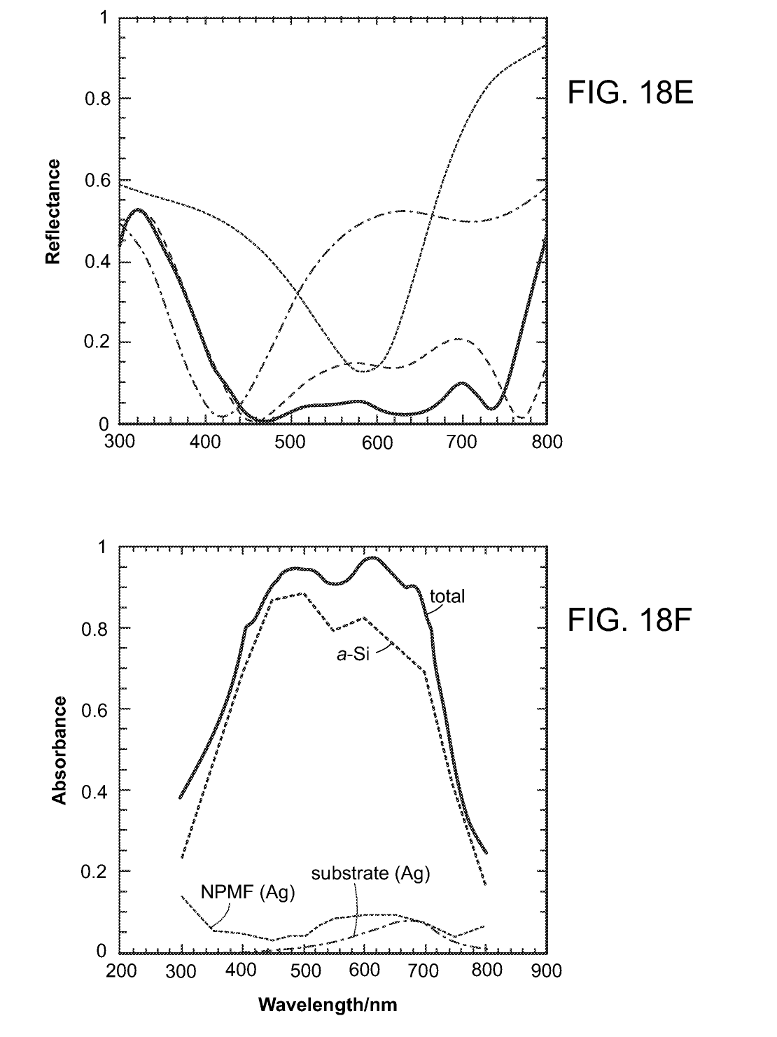

The key task is to discover a specific NPMF structure, which will yield the desired effective ω⁻¹ dependency of ∈_{eff} and μ_{eff}, at least approximately. A good candidate is a percolation threshold structure from a series of periodic structures evolving from islands to perforations, as shown in FIG. 18A and FIG. 18B. This evolution is an analog of the percolation problem (Peng, Y.; Paudel, T.; Chen, W.-C.; Padilla, W. J.; Ren, Z. F.; Kempa, K. Appl. Phys. Letters 2010, 97, 041901.; Kempa, K. Phys. Status Solidi (RRL) 2010, 4, 218-220.; Bergman, D. J.; Imry, Y. Phys. Rev. Lett. 1977, 39, 1222-1225.), and thus it is singular/critical at the percolation threshold pattern (Bergman, D. J.; Imry, Y. Phys. Rev. Lett. 1977, 39, 1222-1225). The effective dielectric function of such structures consists of, as discussed above, electric and magnetic plasmonic resonances. These resonances at the percolation threshold rapidly shift away from their original frequency locations, leaving a smoothly varying ∈_{eff} and μ_{eff}, which resemble the required ω⁻¹ dependency. A particularly singular series of structures is generated from the checkerboard pattern (Kempa, K. Phys. Status Solidi (RRL) 2010, 4, 218-220). (percolation pattern of this series) by uniformly changing the sizes of the checkerboard squares (W×W), but leaving the checkerboard period a unchanged (see FIG. 18B). The patterns to the right and left of the checkerboard pattern form Babinet complementary pairs (Jackson, J. D. Classical Electrodynamics, 3rd ed. John Wiley & Sons Ltd.; New York, 1998), and that the checkerboard pattern itself is a self-Babinet complementary structure. It was shown (Kempa, K. Phys. Status Solidi (RRL) 2010, 4, 218-220.), that the checkerboard pattern can be represented by an effective thin film, with ∈_{eff}˜ω⁻¹, the ideal dependency for the broadband super-absorbance. In the present structure configuration, the NPMF would be designed to be not far from the percolation threshold pattern (checkerboard), and thus μ_{eff} should at least be smoothly varying. Thus, the checkerboard pattern may be a good candidate for the NPMF.

### Example 2

### Computer Simulation Using Suitable PMF Structures

A series of computer simulations for the original (not simplified) structure verify theoretical predictions above, schematically shown in FIG. 16A, with the checkerboard series structures as NPMF. These simulations are based on the high accuracy finite-difference time-domain (FDTD) and finite-difference frequency-domain (FDFD) methods (Taflove, A. Computational Electrodynamics: The Finite-Difference Time-Domain Method. Artech House; Norwood, Mass., 1995. Wang, X.; Kempa, K. Phys. Rev. B 2005, 71, 233101. The following computer software was employed: CST Microwave Studio from the Computer Simulation Technology AG (http://www.cst.com/), and the MEEP from Massachusetts Institute of Technology (http://ab-initio.mit.edu/wiki/index.php/Meep). These have been shown to be quantitative in predicting the performances of nano-optical structures.

These methods identify an optimized structure, unit cell of which is shown in FIG. 18C. Since the NPMF period is a=280 nm and w=145 nm, the pattern is close to the checkerboard, but on the conducting side of the percolation threshold. This allows NPMF to act also as a highly conducting top electrode of a solar cell with a sheet resistance of <10 Ω/γ. Published experimental data (Data for Ag: D. Palik, Handbook of Optical Constants of Solids. Academic Press; Boston, 1985. Data for a-Si and ITO: Sopralab basic n&k files database (http://www.sopra-sa.com/index.php)) were used for all dielectric functions. The optimized absorber thickness is only 15 nm. FIG. 18E shows the simulated reflectance for this optimized structure (bold-solid black line). Indeed, the reflectance suppression is excellent in the entire useful band for the a-Si absorber (400-800 nm).

For comparison, FIG. 18E shows also reflectance for other related structures. The thin-dotted red line is for a structure consisting of only the substrate and the absorber, and as expected it shows very narrow and relatively inefficient reflectance suppression. The thin dashed-dotted red line is for this structure with the IF added. There does not appear to be an improvement of the bandwidth, but instead a blue shift of the minimum. The thin-solid black line is for the structure consisting of the substrate, absorber and the NPMF (but no IF). The reflectance suppression appears broader than that for the structure without NPMF, but still relatively narrow. This changes dramatically (almost threefold increase of the bandwidth) after the IF is added to this structure, yielding the optimized structure discussed above. In addition, a dashed-bold green line represents a result for a complete structure (all films), but with much larger period of the checkerboard (a=750 nm, w=390 nm). It also shows a very broad reflectance suppression, however less efficient than that for the optimal structure. This, on one hand, illustrates that the subwavelength geometry may be preferred in this effect, but on the other, it shows that even outside the subwavelength regime (W˜λ), the band of the suppressed reflectance remains very broad.

FIG. 18D shows the color-encoded map of reflectance (R) as a function of size (W) of the structure and wavelength (λ). It confirms that the suppression bandwidth indeed maximizes not far from the percolation threshold pattern (for W≈120 nm). This band broadening at the percolation threshold can be understood as follows. The structures on either side of the threshold are arrays of discrete elements (islands above the threshold, where W<140 nm, and perforations below, where W>140 nm). These have, as discussed above, localized, narrow band plasmonic resonances. Sufficiently far from the percolation threshold these are degenerate, and thus the effective response is narrowband. At the threshold the inter-island or inter-hole interactions remove the degeneracy, shifting and broadening the resonances. This is somewhat similar to formation of electronic bands in solids from hybridized electronic levels of individual atoms. However, while the usual band formation effects in solids are short range, and thus well described by the tight-binding type of analysis, the interactions near the percolation threshold became critical, i.e., long-range. The fact that the maximum of the bandwidth occurs for W<140 nm (i.e., slightly away from the checkerboard pattern) is in fact expected, and result of interaction of the NPMF with the metallic substrate. This explanation of the band broadening should hold for other percolation threshold structures. To check this, the checkerboard NPMF was replaced with the structures near the percolation threshold of the series shown in FIG. 18A, with similar dimensions. The simulations for this case showed a less efficient R suppression, in a narrower band, and a much less pronounced maximization of the bandwidth at the percolation threshold. Also, after addition of the IF coating, the suppression band remained much narrower than that for the optimized checkerboard structure. Accordingly, checkerboard design may be a possible, preferred NPMF structure.

The reflection suppression in the optimized structure is excellent, and is due to absorption. Furthermore, this absorption can be engineered to be overwhelmingly in the absorber (a-Si), and not in the metal (Ag). To show that, further simulations were performed for the optimized structure with lossless IF (e.g., lossless ITO), and with best bulk quality Ag (Johnson, P. B. and Christy, R. W. Phys. Rev. B 1972, 6, 370.), recently demonstrated experimentally with nanoscopically thin films (Chen, W., Thoreson, M. D., Ishii, S., Kildishev, A. V., and Shalaev, V. M., Optics Express 2010, 18, 5124). FIG. 18F shows the total absorbance, as well as the partial absorbances in the absorber, and Ag layers (NPMF and substrate). IF is made of the lossless ITO ∈_{ITO}=3.8), and the dielectric function of Ag is taken from Kempa, K.; Naughton, M. J.; Ren, Z. F.; Herczynski, A.; Kirkpatrick, T.; Rybczynski, J.; Gao, Y. Appl. Phys. Lett., 2009, 95, 233121). It appears that the absorbance in the a-Si absorber dominates.

To estimate the potential photovoltaic performance of the structure the absorbance in the a-Si only was used, as shown in FIG. 18F (bold-dotted line). This absorbance, which with high-quality p-i-n junctions is essentially identical to the external quantum efficiency (Springer, J.; Poruba, A.; Vanecek, M. Journal of Applied Physics 2004, 96, 5329.), can be integrated (Kr\check{c}, J.; Smole, F.; Topi\check{c}, M. Prog. Photovolt: Res. Appl. 2003, 11, 15.) with the solar power spectrum (AM 1.5) to yield the expected short circuit current density J_{sc}, an important parameter of solar cells. A high current density of J_{sc}=19.7 mA/cm² was obtained, much higher than J_{sc}=17 mA/cm² of the present record experimental efficiency champion in single-junction a-Si solar cell (Meier, J.; Spitznagel J.; Kroll, U.; Bucher, C.; Faÿ, S.; Moriarty, T.; Shah, A. Thin Solid Films, 2004, 451-452, 518-524). Experimental results with ultra-thin, planar a-Si p-i-n junctions, show that these indeed can be of excellent quality (Kr\check{c}, J.; Smole, F.; Topi\check{c}, M. Prog. Photovolt: Res. Appl. 2003, 11, 15). For example (Kempa, K.; Naughton, M. J.; Ren, Z. F.; Herczynski, A.; Kirkpatrick, T.; Rybczynski, J.; Gao, Y. Appl. Phys. Lett., 2009, 95, 233121), an un-optimized junction with p, i, n layers of 5, 10, 5 nm in thickness, respectively, achieved a fill factor FF=0.7, and an open circuit voltage V_{oc}=0.87 V, at much lower current density of 4.6 mA/cm² due to inefficient light absorption. It was also demonstrated that these ultra-thin (<5 nm) p and n layers strongly contribute to the generated photocurrent (Kr\check{c}, J.; Smole, F.; Topi\check{c}, M. Prog. Photovolt: Res. Appl. 2003, 11, 15.). Using parameters of these junctions with the simulated current density J_{sc}=19.7 mA/cm² yields a conservatively estimated efficiency of 12%. With further optimization of such ultra-thin junctions, 15% efficiency of the structure is possible.

### Example 3

### Protection of Hot Electrons

The scattering rate of an excited electron from the state Eₖ to all states E_{k+q}, due to single particle and collective (plasmon) excitations (with wave vectors q) is given by (G. D. Mahan, Many-particle physics, (Plenum Press, New York 1981).; J. J. Quinn, R. A. Ferrell, Phys. Rev. 112, 812 (1958).; R. D. Mattuck, A Guide to Feynman Diagrams in the Many-Body Problem. (McGraw-Hill, New York, 1976); T. D. Schultz, Quantum Field Theory and the Many-Body Problem, (Gordon and Breach, New York, 1964).; K. Kempa, P. Bakshi, J. Engelbrecht and Y. Zhou, Phys. Rev. B 61, 11083 (2000).)

$${γ}_{k} \approx - \frac{2}{ℏ} \int \frac{d q}{{( 2 π )}^{3}} {v}_{q} [ {n}_{B} ( {E}_{k} - {E}_{k + q} ) - {n}_{F} ( - {E}_{k + q} + μ ) ] Im [ {V}_{eff} [ q , ( {E}_{k + q} - {E}_{k} ) / ℏ ] ] \qquad ( 1 )$$

where n_{B} and n_{F} are the Bose-Einstein and Fermi-Dirac distribution functions correspondingly, μ is the chemical potential, v_{q} is the bare Coulomb interaction, and V_{eff}(q,ω) is the dressed combined interaction, which can be written as a simple sum of the Coulomb and phonon (Frohlich) terms (G. D. Mahan, Many-particle physics, (Plenum Press, New York 1981).; R. D. Mattuck, A Guide to Feynman Diagrams in the Many-Body Problem. (McGraw-Hill, New York, 1976); T. D. Schultz, Quantum Field Theory and the Many-Body Problem, (Gordon and Breach, New York, 1964).)

$${V}_{eff} ( q , ω ) = \frac{{V}_{q}}{ɛ ( q , ω )} + \frac{{Ω}_{q} {\vert {g}_{q} / ɛ ( q , ω ) \vert}^{2}}{{ω}^{2} - {Ω}_{q}^{2} / ɛ ( q , ω ) + i {0}^{+}} \qquad ( 2 )$$

where ∈(q,ω) is the longitudinal dielectric function of the medium, g_{q} is the matrix element, is the longitudinal phonon frequency (plasma frequency of the ionic “plasma”). Eq. (2) is written in the random phase approximation (RPA) for electrons (first term), and the point-ion, long wavelength approximation for ions (second term) [6,8].

From Eq. (2) it appears that the electron scattering is controlled by that with other electrons (first, Coulomb term), and phonons (second, Frohlich term). It also appears that the strongest contribution to the electron-electron scattering comes from the collective branch (plasmons), for which ∈(q,ω) vanishes. The electron-phonon scattering rate, given by Eq. (1) with the dressed phonon interaction (second term in Eq. (2)), has been calculated and/or simulated for a variety of systems, and for most bulk systems is of the same order of 10¹⁴ sec⁻¹. This is related to the order of magnitude the same atomic density of most solids, and thus similar ionic “plasma” frequency Ω_{q}. It has been also known to be relatively insensitive to sample structuring (except for nanoscopic structuring). This is related to the (on average) short wavelength of phonons at the maximum of the density of states (DOS), and mostly incoherent nature of the phononic states. In contrast, the electron-plasmon scattering is extremely sensitive to both, electron density and sample structuring.

Next, the electron-plasmon scattering can be calculated for a specific system of a PMN embedded, or strongly coupled to (placed in close vicinity of) a medium (semiconductor), for which, it can be assumed, the electron-phonon scattering is known, and identical to that in the bulk (i.e. without PMN).

It was shown, that the electromagnetic response of PMN can be well described, in the effective medium model, by an effective, local dielectric function of the general form as follows: (K. Kempa, Phys. Rev. B 74, 033411 (2006).; Y. Peng, T. Paudel, W. C. Chen, W. J. Padilla, Z. F. Ren, and K. Kempa, Appl. Phys. Lett. 97, 041901 (2010).; K. Kempa, Phys. Status Solidi RRL 4, 218 (2010).)

$$ɛ ( ω ) = {ɛ}_{back} + {\sum }_{f = 1}^{M} \frac{{ω}_{pf}^{2}}{{ω}_{rf}^{2} - {ω}^{2}} \qquad ( 3 )$$

where ω is the frequency of the electromagnetic radiation, and ω_{rf}, ω_{pf}, and ∈_{back} are constants. For the 2D island arrays ω_{rf}≠0, but the 2D hole arrays must have ωᵣ₁=0. Bulk, longitudinal plasmons occur anytime ∈(ω)=0. The simplest form of Eq. (2), which includes propagating and trapped plasmon modes is

$$ɛ ( ω ) = {ɛ}_{b} + \frac{{ω}_{p}^{2}}{{ω}_{r}^{2} - {ω}^{2}} \qquad ( 4 )$$

This form is an exact effective dielectric function for the 3D point-dipole crystal (Kempa, R. Ruppin, and J. B. Pendry, Phys. Rev. B 72, 1 (2005).), and (with ωᵣ=0) can be used to describe the extraordinary optical transmission (EOT) (T. W. Ebbesen et al. Nature 391 667 (1998).) of nanoscopically perforated metallic films in the subwavelength limit (J. B. Pendry, L. Martin-Moreno, and F. J. Garcia-Vidal, Science 305, 847 (2004).; Y. Wang, E. W. Plummer, and K. Kempa, Foundations of Plasmonics, Advances in Physics 60, 799 (2011).). With ∈(q,ω) given by Eq. (4), and at room temperatures, the following, explicit expression for the electron-plasmon scattering rate in the proposed system can be obtained from Eq. (1) and Eq. (2) with the Coulomb term only:

$$\begin{matrix}{γ}_{el - pl} \approx \frac{\sqrt{2 {E}_{k} / {m}^{*}}}{2 {a}_{0}^{*}} f ( \frac{{E}_{k}}{{E}_{0}} ) θ ( \frac{{E}_{k}}{{E}_{0}} - 1 ) \\ where & ( 5 ) \\ {a}_{0}^{*} = {h}^{2} {ɛ}_{b} / {m}^{*} {e}^{2} & ( 6 ) \\ {E}_{0} = {\frac{h {ω}_{p}}{\sqrt{{ɛ}_{b}}} [ {ɛ}_{b} \sqrt{1 + {{ɛ}_{b} ( {ω}_{r} / {ω}_{p} )}^{2}} ]}^{- 1} & ( 7 ) \\ f ( x ) = \frac{2}{x} ln [ \sqrt{x} + \sqrt{x - 1} ] & ( 8 )\end{matrix}$$

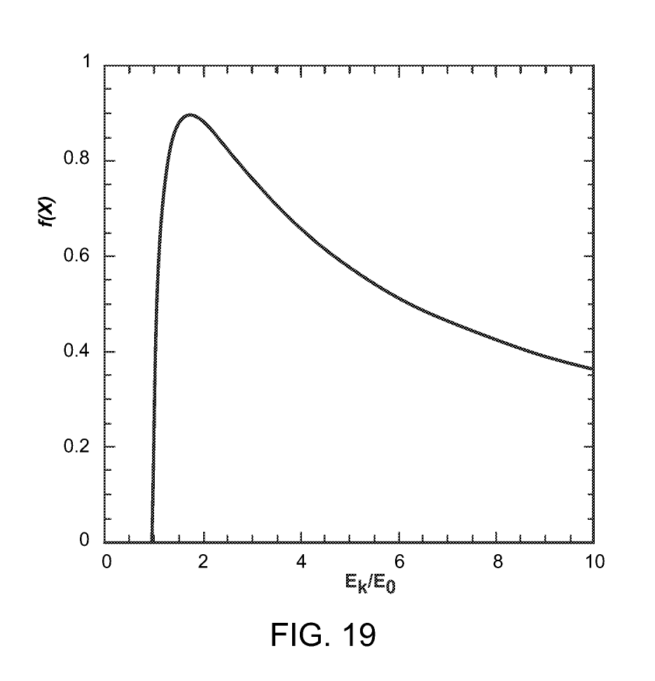

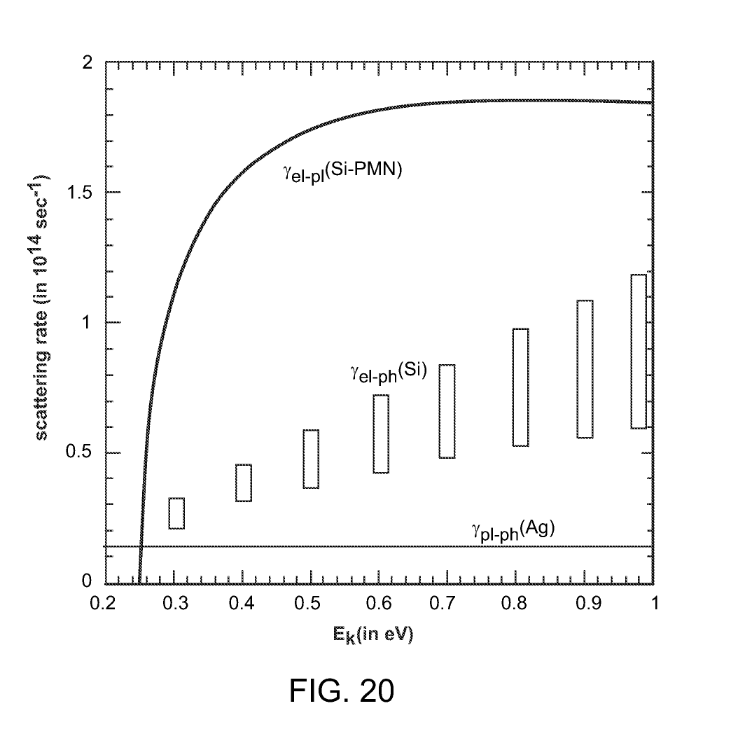

In the limit of ∈_{b}=1 and ωᵣ=0 (for which E₀=hωₚ), Eq. (5) reduces to the well-known form for bulk metals (G. D. Mahan, Many-particle physics, (Plenum Press, New York 1981).). It was shown, that with a more realistic model of the metallic dielectric response (RPA), the results change only marginally (to within ˜10%), and that these results are in agreement with experiment (G. D. Mahan, Many-particle physics, (Plenum Press, New York 1981). The universal auxiliary function, given by Eq. (8), and which controls the Eₖ dependency of γₑₗ₋ₚₗ, is plotted in FIG. 19. It shows that the electron-plasmon scattering occurs for Eₖ>E₀, an effective plasmon frequency of PMN, and the rate sharply picks at about 1.7 E₀, emphasizing the known fact, that a few plasmon scattering is preferential (G. D. Mahan, Many-particle physics, (Plenum Press, New York 1981).). The calculation of the electron-plasmon scattering rate γₑₗ₋ₚₗ, obtained from Eq. (5) with parameters for crystalline silicon and PMN designed so that E₀=0.25 eV, for various values of the initial electron energy Eₖ is shown in FIG. 20 (bold solid line). The rate is very high, and well exceeds in the entire range of Eₖ the electron-phonon scattering rate γₑₗ₋ₚₕ, which is represented by the vertical bars, and was simulated elsewhere by various methods (M. V. Fichetti and S. Laux, J. Appl. Phys. 80, 2234 (1996); [18] M. Michaillat et al., Thin Solid Films 518, 2437 (2010).; O. D. Restrepo at al., J. Appl. Phys. 94, 212103 (2009).; Y. M. Niquet, D. Rideau, C. Tavernier, H. Jaouen and X. Blas, Phys. Rev. B 79, 245201 (2009).; D. Rideau, W. Zhang, Y. M. Niquet, C. Delerue, C. Tavrnier, H. Jaouen, Electron-phonon scattering in Si and Ge: From bulk to nanodevices, 2011 International Conference on Simulation of Semiconductor Processes and Devices (SISPAD), Conference Publication, page 47-50.), including ab initio calculation, which yields electron mobilities in excellent agreement with experiment. Note, that this conclusion is unchanged, if instead of one, there are many electrons excited in the semiconductor band. Then both rates (γₑₗ₋ₚₗ and γₑₗ₋ₚₕ) are getting smaller, as a result of a shrinking momentum space for available transitions, but essentially by the same factor, so that their ratio is preserved. Even though, the electron-plasmon scattering “outperforms” the electron phonon scattering, use of the PMN as a plasmonic reservoir, “protecting” the electron energy from phonon dissipation, rests on stability of this reservoir against the phonon and radiative losses, i.e. it can be shown that the plasmon-phonon and plasmon-photon scattering rates in PMN are much smaller than the electron-phonon scattering in the semiconductor, i.e. γₚₗ₋ₚₕ<<γₑₗ₋ₚₕ and γₚₗ₋ₚₕₒₜ<<γₑₗ₋ₚₕ.

To estimate γₚₗ₋ₚₕ, it is first noticed that dispersion of any plasmonic (or polaritonic) mode is given in general by

F[∈(q,ω)]=0 (9)

where F[x] is an analytic function of x. Let assume, that Eq. (9) has the following solution ω=ω₀(q). A general way to account for losses in expressions for the dielectric functions (of the form Eq. (4)) is to replace ω² with ω(ω+iγ), where γ is the rate of inelastic scattering with the lattice (essentially an average of γₑₗ₋ₚₕ^{k}). Parameter γ is known experimentally for most metals. Now, consider the following expression

$$\overline{ω} = \sqrt{{ω}_{0}^{2} ( q ) - \frac{{γ}^{2}}{4}} - i \frac{γ}{2} \qquad ( 10 )$$

Since, ω̅( ω̅+iγ)=ω₀²(q), and Eq. (2) contains only ω² (replaced with ω(ω+iγ)), this implies that ω= ω̅ is also a solution to Eq. (9), and thus any plasmonic (polaritonic) mode scatters with phonons at an average rate of γ/2. Since for silver (best plasmonic metal) γ≈0.25×10¹⁴ (sec)⁻¹ (Johnson, P. B. and Christy, R. W. Phys. Rev. B 1972, 6, 370.), we find γₚₗ₋ₚₕ≈γ/2≈0.125×10¹⁴ (sec)⁻¹<<γ_{el-ph*}γₚₗ₋ₚₕ is represented in FIG. 20 as a thin-horizontal line. FIG. 20 illustrates a graph of electron scattering rates of hot electrons in silicon. Scattering with plasmons in PMN (calculated from Eq. (5), bold-solid line), with phonons in silicon (simulations done elsewhere, vertical bars). The horizontal thin-solid line represents the plasmon-phonon scattering rate in PMN, estimated from Eq. (10). All plotted versus the electron energy Eₖ. This estimated plasmon-phonon scattering rate agrees well with the Mie plasmon peak broadening due to the Drude damping, as calculated and measured in Ref. [23] for PMN consisting of a planar, periodic array of ellipsoidal Ag nanopartitles (80 nm×40 nm) with the lattice period of 200 nm.

To estimate γₚₗ₋ₚₕₒₜ, it is noted that this radiative damping scales as ω⁴ (J. D. Jackson, Classical Electrodynamics, 3rd ed., Wiley, NewYork, 1998; J. A. Kong, Electromagnetic Wave Theory, EMW Publishing, Cambridge, Mass., 2005), and thus it is not expected to be important at the IR frequencies. This is fully confirmed by detailed calculations in M. Scharte, R. Porath, T. Ohms, M. Aeschlimann, J. R. Krenn, H. Ditlbacher, F. R. Aussenegg, and A. Liebsch, Appl. Phys. B 73, 305 (2001)., which show that while γₚₗ₋ₚₕₒₜ>γ in the visible frequency range, it is only γₚₗ₋ₚₕₒₜ≈10¹¹ (sec)⁻¹ at the frequency of the plasmon resonance E₀=0.25 eV, and thus γₚₗ₋ₚₕₒₜ<<γ, and therefore this plasmon-photon scattering process can be here ignored.

With these results, FIG. 19 demonstrates that electron-plasmon scattering process is faster than the electron-phonon process in the semiconductor, and much faster than any scattering processes in PMN in the entire relevant energy range. This is the condition for the plasmonic protection; once the hot electron energy is transferred to plasmons in PMN, it remains there protected from all relevant emissions (phonons and photons).

### Example 4

### Recovery of the Stored Energy from Plasmonic Reservoir

In some embodiments, to recovery the stored energy from the plasmonic reservoir, the PMN structure may be strongly coupled to the excited electron/electrons in the semiconductor, which could transform the excited plasmon into a plasmaron, a coupled plasmon-single particle excitation. In addition, the plasmonic/plasmaronic resonator (PMN) acts as a high Q resonator of the electromagnetic field. Thus, the conditions can arise for Rabi-like oscillations, in which energy of the hot electron oscillates between the electron and the plasmonic/plasmaronic reservoir. The period of these oscillations is expected to be proportional to the matrix element involving the initial and final states of the hot electron, and the electric field of the reservoir (PMN structure).

In some embodiments, a metamaterial structure comprises a light absorbing layer capable of absorbing solar energy and converting the absorbed energy into electrical current, a first patterned metallic layer disposed on a light absorbing surface of the light absorbing layer, the first patterned metallic layer being configured to increase light absorption in the light absorbing layer, and a second patterned metallic layer disposed in proximity to the light absorbing layer, the second patterned metallic layer being configured to control phonon-scattering by storing or protecting the hot electron energy in the light absorbing layer.

In some embodiments, a photovoltaic cell includes a light absorbing layer capable of absorbing solar energy and converting the absorbed energy into electrical current, a first patterned metallic layer disposed on a light absorbing surface of the light absorbing layer, the first patterned metallic layer being configured to increase light absorption in the light absorbing layer, a second patterned metallic layer disposed in proximity to the light absorbing layer, the second patterned metallic layer being configured to control phonon-scattering in the light absorbing layer, and a rear electrode disposed on a surface of the absorbing layer opposite to the light absorbing surface of the light absorbing layer, the rear electrode and the first patterned metallic layer in electrical communication with the absorbing layer to collect electrical current generated in the light absorbing material.

In some embodiments, a method for increasing conversion efficiency in a solar cell includes disposing a first patterned metallic layer on a light absorbing surface of a light absorbing layer, wherein the light absorbing layer is capable of absorbing solar energy and converting the absorbed energy into electrical current; disposing a second patterned metallic layer in proximity to the light absorbing layer; allowing the light absorbing layer to absorb light; and collecting electrical current generated in the absorbing layer by a rear electrode disposed on a surface of the absorbing layer opposite to the light absorbing surface of the light absorbing layer, wherein the first and second patterned metallic layers in combination increase the power conversion efficiency of the absorbed solar energy in to electrical energy.

All patents, patent applications, and published references cited herein are hereby incorporated by reference in their entirety. While the devices and methods of the present disclosure have been described in connection with the specific embodiments thereof, it will be understood that they are capable of further modification. Furthermore, this application is intended to cover any variations, uses, or adaptations of the devices and methods of the present disclosure, including such departures from the present disclosure as come within known or customary practice in the art to which the devices and methods of the present disclosure pertain, and as fall within the scope of the appended claims.

What is claimed is:

1. A metamaterial structure comprises:
a light absorbing layer capable of absorbing solar energy and converting the absorbed energy into electrical current;
a first patterned layer disposed on a light absorbing surface of the light absorbing layer, the first patterned layer being configured to increase light absorption in the light absorbing layer;
a second patterned layer disposed in proximity to the light absorbing layer, the second patterned layer being configured to control phonon-scattering by storing or protecting the hot electron energy in the light absorbing layer.

2. The metamaterial structure of claim 1 wherein the light absorbing layer is a photovoltaic junction and the first pattered layer and the second patterned layer are made of metal.

3. The metamaterial structure of claim 1 wherein the light absorbing layer is a photovoltaic junction having a thickness of between about 1 nanometer and about 1000 nanometers.

4. The metamaterial structure of claim 1 wherein the first patterned layer is patterned with an array of perforations with the array period of between about 100 nm and about 1000 nm and the perforations being less than about 500 nm.

5. The metamaterial structure of claim 1 wherein the first patterned layer is patterned with an array of conductive islands having all dimensions of less than about 500 nm.

6. The metamaterial structure of claim 1 wherein the second patterned layer has a thickness of between about 20 nm and about 100 nm.

7. The metamaterial structure of claim 1 wherein the second patterned layer is patterned with an array of perforations with the array period of between about 50 nm and about 500 nm and the perforations having dimensions between about 50 nm and about 5000 nm.

8. The metamaterial structure of claim 1 wherein the first patterned layer is designed to absorb in the visible light spectrum and the second patterned layer is designed to absorb in the infrared spectrum.

9. The metamaterial structure of claim 1 wherein the second patterned layer is located on a surface of the light absorbing layer.

10. The metamaterial structure of claim 1 wherein the second patterned layer is embedded in the light absorbing layer.

11. The metamaterial structure of claim 1 wherein the second patterned layer is spaced away from the light absorbing layer.

12. The metamaterial structure of claim 1 wherein the light absorbing layer is positioned between a front resonant tunneling filter and a back resonant tunneling filter.

13. A photovoltaic cell comprising the metamaterial structure of claim 1 and a rear electrode disposed on a surface of the absorbing layer opposite to the light absorbing surface of the light absorbing layer, the rear electrode and the first patterned metallic layer in electrical communication with the absorbing layer to collect electrical current generated in the light absorbing material.

14. The photovoltaic cell of claim 13 further comprising an anti-reflective coating disposed on the light absorbing layer and having a thickness less than about 500 nm.

15. A method for increasing conversion efficiency in a solar cell comprising:
disposing a first patterned metallic layer on a light absorbing surface of a light absorbing layer, wherein the light absorbing layer is capable of absorbing solar energy and converting the absorbed energy into electrical current;
disposing a second patterned metallic layer in proximity to the light absorbing layer;
allowing the light absorbing layer to absorb light; and
collecting electrical current generated in the absorbing layer by a rear electrode disposed on a surface of the absorbing layer opposite to the light absorbing surface of the light absorbing layer, wherein the first and second patterned metallic layers in combination increase the power conversion efficiency of the absorbed solar energy into electrical energy.

16. The method of claim 15 wherein the light absorbing layer is a photovoltaic junction having a thickness of between about 1 nanometer and about 1000 nanometers.

17. The method of claim 15 wherein the first patterned layer is patterned with an array of perforations with the array period of between about 100 nm and about 1000 nm and the perforations being less than about 500 nm or is patterned with an array of conductive islands having all dimensions of less than about 500 nm.

18. The method of claim 15 wherein the second patterned layer has a thickness of between about 20 nm and about 100 nm and is patterned with an array of perforations with the array period of between about 50 nm and about 500 nm and the perforations having dimensions between about 50 nm and about 5000 nm.

19. The method of claim 15 wherein the first patterned layer is designed to absorb in the visible light spectrum and the second patterned layer is designed to absorb in the infrared spectrum.

20. The method of claim 15 wherein the second patterned layer is located on a surface of the light absorbing layer, the second patterned layer is embedded in the light absorbing layer, or the second patterned layer is spaced away from the light absorbing layer.
